(19) United States
(12) Patent Application Publication
(10) Pub. No.: US 2026/0293121 A1
(43) Pub. Date: Sep. 24, 2026

(54) SEMICONDUCTOR MEMORY DEVICE

(71) Applicant: SAMSUNG ELECTRONICS CO., LTD., Suwon-si (KR)

(72) Inventors: Jaeho Kim, Suwon-si (KR); Hyojin Park, Suwon-si (KR); Sung-Hwan Jang, Suwon-si (KR); Soonwook Jung, Suwon-si (KR)

(73) Assignee: SAMSUNG ELECTRONICS CO., LTD., Suwon-si (KR)

(21) Appl. No.: 19/421,508

(22) Filed: Dec. 16, 2025

(30) Foreign Application Priority Data
Mar. 24, 2025 (KR) 10-2025-0037443

(51) Int. Cl. H10B 12/00; H10D 1/68; H10D 62/60

(52) U.S. Cl. CPC H10B 12/488; H10B 12/482; H10D 1/714; H10D 62/60; H10B 12/05

(57) ABSTRACT

A semiconductor memory device comprises a substrate, a word line extending in a first direction parallel to a top surface of the substrate, a semiconductor pattern having a long axis in a second direction intersecting the first direction and penetrating the word line, a gate insulating layer between the word line and the semiconductor pattern, a bit line extending in a third direction perpendicular to the top surface of the substrate and connected to a first end of the semiconductor pattern, a storage node electrode connected to a second end opposite to the first end of the semiconductor pattern, a contact pattern interposed between the storage node electrode and the second end of the semiconductor pattern, wherein the contact pattern can comprise a contact portion contacting the semiconductor pattern and a horizontal portion extending from the contact portion in the second direction to define a recess region.

### CROSS-REFERENCE TO RELATED APPLICATIONS

This U.S. non-provisional patent application claims priority under 35 U.S.C. §119 to Korean Patent Application No. 10-2025-0037443 filed on March 24, 2025, in the Korean Intellectual Property Office, the entire contents of which are hereby incorporated by reference.

### BACKGROUND

The present disclosure relates to a semiconductor memory device, and more particularly, to a three-dimensional semiconductor memory device with more improved reliability and integration.

An electronic system that uses data storage may require a semiconductor device capable of storing a large amount of data. Accordingly, research on methods for increasing data storage capacity of semiconductor devices has been conducted. For example, a semiconductor device comprising memory cells three-dimensionally arranged, instead of arranging the memory cells two-dimensionally, has been proposed as one of the methods for increasing the data storage capacity of the semiconductor device.

### SUMMARY

Some embodiments of the disclosure provide a semiconductor memory device with more improved reliability and integration.

The object of the disclosure is not limited to the goal mentioned above, and other technical goals that are not mentioned may be clearly understood from description below by those skilled in the art.

According to some embodiments of the present disclosure, a semiconductor memory device may include a substrate, a word line extending in a first direction parallel to a top surface of the substrate, a semiconductor pattern penetrating the word line and having a long axis in a second direction intersecting the first direction, a gate insulating layer between the word line and the semiconductor pattern, a bit line extending in a third direction perpendicular to the top surface of the substrate and connected to a first end of the semiconductor pattern, a storage node electrode connected to a second end opposite to the first end of the semiconductor pattern, and a contact pattern interposed between the storage node electrode and the second end of the semiconductor pattern. The contact pattern may include a contact portion contacting the semiconductor pattern and a horizontal portion extending from the contact portion in the second direction to define a recess region.

According to some embodiments of the present disclosure, a semiconductor memory device may include a substrate, a stacked structure including word lines and interlayer insulating patterns alternately stacked on the substrate, the word lines extending in a first direction parallel to a top surface of the substrate, semiconductor patterns intersecting the word lines and having a long axis in a second direction parallel to the top surface of the substrate, the semiconductor patterns spaced apart from each other on the substrate in the first direction and in a third direction perpendicular to the top surface of the substrate, bit lines disposed at one side of the stacked structure and spaced apart from each other in the first direction, each of the bit lines being connected to first ends of the semiconductor patterns spaced apart in the third direction, storage node electrodes each connected to second ends opposite the first ends of the semiconductor patterns, contact patterns interposed between the storage node electrodes and the second ends of the semiconductor patterns, a capacitor dielectric layer conformally covering the storage node electrodes, and a plate electrode on the capacitor dielectric layer. Each of the contact patterns may include a contact portion contacting the semiconductor pattern and a horizontal portion extending from the contact portion in the second direction to define a recess region. In the third direction, each of the semiconductor patterns may have a first thickness, and each of the storage node electrodes may have a second thickness that is greater than the first thickness.

According to some embodiments of the present disclosure, a semiconductor memory device may include a substrate, a stacked structure including word lines and interlayer insulating patterns alternately stacked on the substrate, the word lines extending in a first direction parallel to a top surface of the substrate, semiconductor patterns traversing the word lines and having a long axis in a second direction parallel to the top surface of the substrate, the semiconductor patterns being spaced apart in the first direction and in a third direction perpendicular to the top surface the substrate, bit lines extending in the third direction and spaced apart from each other in the first direction, each of the bit lines connected to first ends of the semiconductor patterns spaced apart in the third direction, storage node electrodes respectively connected to second ends opposite the first ends of the semiconductor patterns, contact patterns interposed between the storage node electrodes and the second ends of the semiconductor patterns, silicide patterns interposed between the storage node electrodes and the contact patterns, a capacitor dielectric layer conformally covering the storage node electrodes, and a plate electrode on the capacitor dielectric layer. Each of the contact patterns may include a contact portion contacting the semiconductor pattern and a horizontal portion extended from the contact portion in the second direction. Each of the silicide patterns may include a recess region, and a portion of the storage node electrode may be disposed within the recess region of the silicide pattern.

### BRIEF DESCRIPTION OF DRAWINGS

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Aspects of the disclosure will become more apparent by describing in detail embodiments thereof with reference to the attached drawings and accompanying detailed description.

FIG. 1 is a plan view illustrating a portion of a semiconductor memory device according to embodiments of the disclosure.

FIGS. 2A, 2B, and 2C, are cross-sectional views taken along lines A-A′, B-B′, and C-C′ of FIG. 1 to illustrate a semiconductor memory device according to embodiments of the disclosure.

FIGS. 3A, 3B, and 3C, are enlarged views of the P1 portion of FIG. 2A.

FIG. 4 is a perspective view illustrating a portion of a semiconductor memory device according to embodiments of the disclosure.

FIGS. 5A, 6A, 7A, 8A, 9A 10A, 11A, 12A, and 13A, are plan views to illustrate a method for manufacturing a semiconductor memory device according to embodiments of the disclosure.

FIGS. 5B, 6B, 7B, 8B, 9B and 10B are cross-sectional views taken along a line A-A′ and a line B-B′ of FIGS. 5A, 6A, 7A, 8A, 9A and 10A.

FIGS. 11B, 12B, and 13B, are cross-sectional views taken along a line A-A′ and a line C-C′ of FIGS. 11A, 12A, and 13A.

FIGS. 14A, 14B, 14C, 14D, and 14F, are enlarged views of a portion ‘P2’ of FIG. 13B to illustrate a method for manufacturing a semiconductor memory device according to embodiments of the disclosure.

FIGS. 15A, 15B, and 15C, are enlarged views of a portion ‘P2’ of FIG. 13B. to illustrate a method for manufacturing a semiconductor memory device according to embodiments of the disclosure.

### DETAILED DESCRIPTION

Example embodiments of the disclosure will now be described more fully with reference to the accompanying drawings, in which example embodiments are shown.

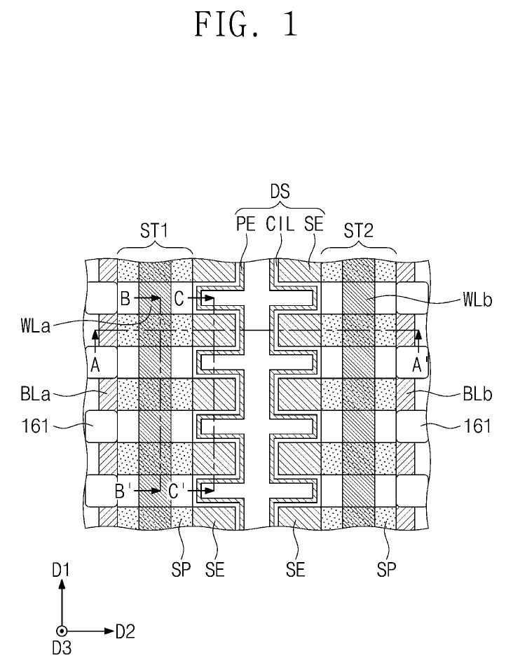

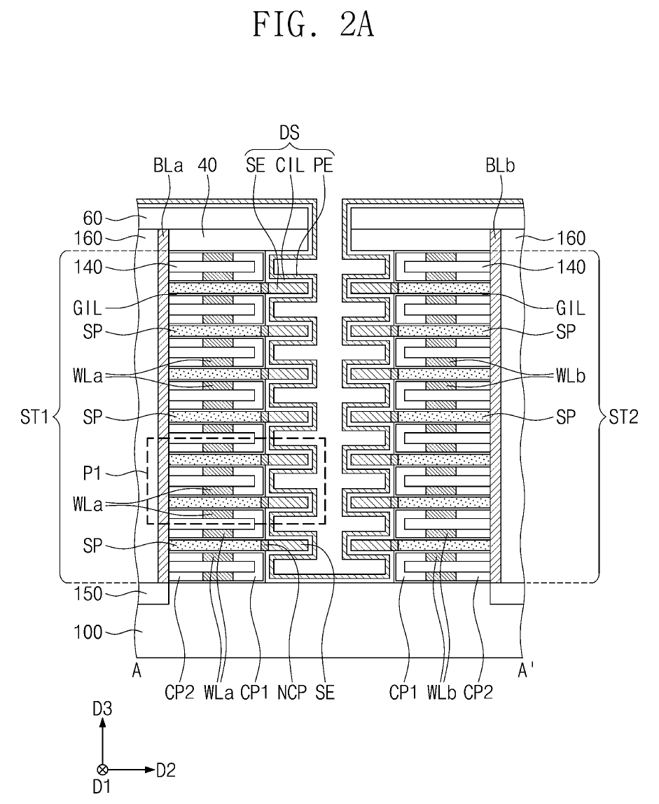

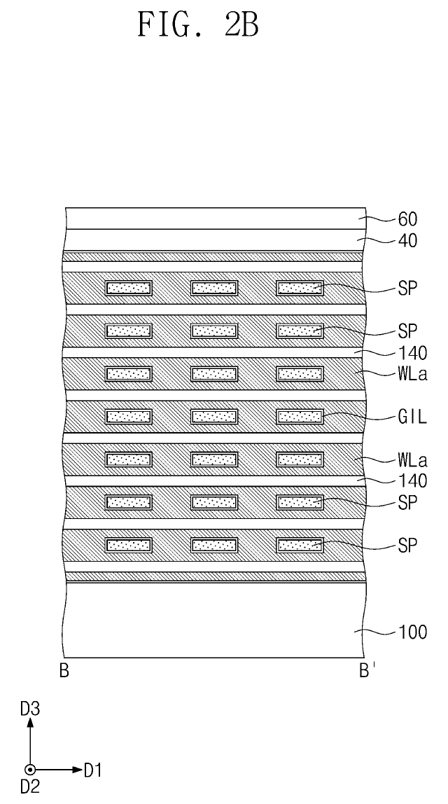

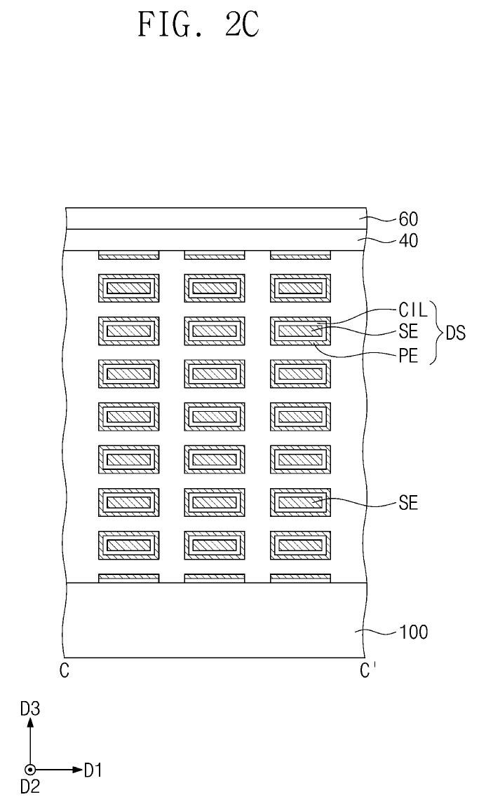

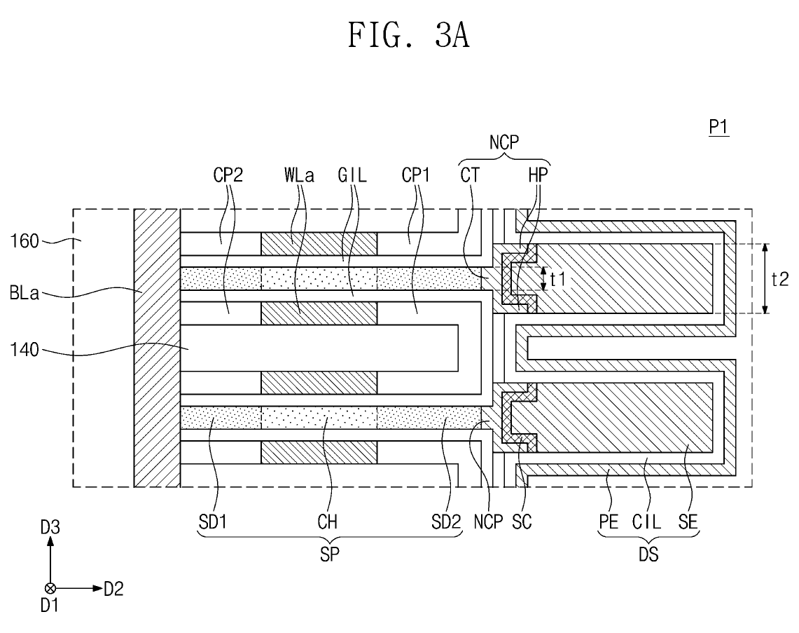

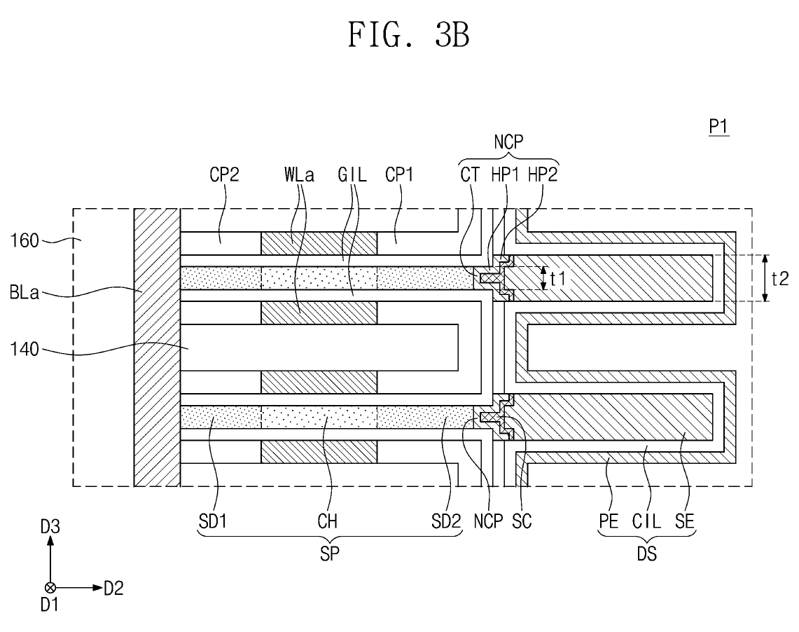

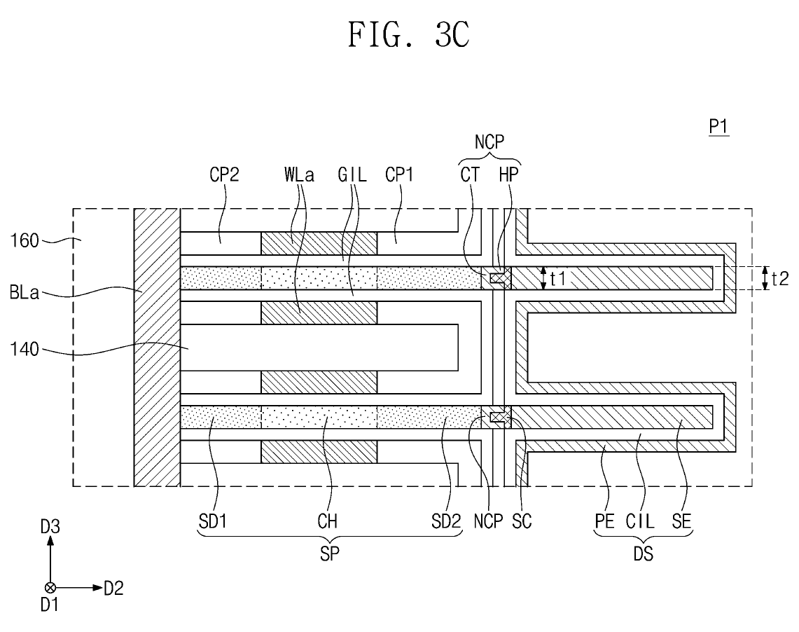

FIG. 1 is a plan view illustrating a portion of a semiconductor memory device according to embodiments of the disclosure. FIGS. 2A, 2B, and 2C, are cross-sectional views taken along lines A-A′, B-B′, and C-C′ of FIG. 1 to illustrate a semiconductor memory device according to embodiments of the disclosure. FIGS. 3A, 3B, and 3C, are enlarged views of the P1 portion of FIG. 2A.

Referring to FIGS. 1, 2A, 2B, and 2C, first and second stacked structures ST1 and ST2 may be disposed on a substrate 100.

The substrate 100 may be a semiconductor substrate, an insulator substrate, a silicon-on-insulator (SOI) substrate, or a germanium-on-insulator (GOI) substrate. The semiconductor substrate may be, for example, a silicon substrate, a germanium substrate or a silicon-germanium substrate.

The first and second stacked structures ST1, ST2 may extend along a first direction D1 parallel to a top surface of the substrate 100, and may be spaced apart from each other in a second direction D2 intersecting the first direction D1 and parallel to the top surface of the substrate 100.

The first stacked structure ST1 may include first word lines WLa stacked on the substrate 100 along a third direction D3, with interlayer insulating patterns 140 interposed therebetween. The second stacked structure ST2 may include second word lines WLb stacked in the third direction D3 on the substrate 100, with the interlayer insulating patterns 140 interposed therebetween.

In some embodiments, each of the first and second word lines WLa, WLb may have a structure (i.e., a gate-all-around structure) that completely surrounds semiconductor patterns SP arranged along the first direction D1. Alternatively, each of the first and second word lines WLa, WLb may have a double gate structure provided on top surfaces and bottom surfaces of the semiconductor patterns SP arranged along the first direction D1.

The first and second word lines WLa, WLb may be, for example, any one of a doped semiconductor material (e.g., doped silicon, doped germanium, etc.), a conductive metal nitride (e.g., titanium nitride, tantalum nitride, etc.), metal (e.g., tungsten, titanium, tantalum, etc.) or a metal-semiconductor compound (e.g., tungsten silicide, cobalt silicide, titanium silicide, etc.).

When viewed in a plan view, the pair of first and second word lines WLa, WLb may be mirror-symmetrical to each other with respect to a plate electrode PE.

A first hard mask pattern 40 may be disposed on each of the first and second stacked structures ST1, ST2. The first hard mask pattern 40 may be, for example, a silicon oxide layer or a silicon nitride layer.

Each of the first and second stacked structures ST1, ST2 may include semiconductor patterns SP arranged along the first direction D1 and stacked in the third direction D3 perpendicular to the top surface of the substrate 100.

Each of the semiconductor patterns SP may have a bar shape that crosses the first or second word lines WLa, WLb and may have a long axis in the second direction D2.

The semiconductor patterns SP may include silicon (Si), germanium (Ge), or silicon-germanium (SiGe). For example, the semiconductor patterns SP may be formed of single crystal silicon. In some embodiments, the semiconductor patterns SP may have a greater bandgap energy than silicon. For example, the semiconductor patterns SP may have a bandgap energy of about 1.5 eV to 5.6 eV. For example, when the semiconductor patterns SP have a bandgap energy of about 2.0 eV to about 4.0 eV, the semiconductor patterns SP may have an optimal channel performance. For example, the semiconductor patterns SP may include an oxide semiconductor, and the oxide semiconductor may include, for example, ZnₓSn_{y}O (ZTO), InₓZn_{y}O (IZO), ZnₓO, InₓGa_{y}Zn_{z}O (IGZO), InₓGa_{y}Si_{z}O (IGSO), InₓW_{y}O (IWO), InₓO, SnₓO, TiₓO, ZnₓONz, MgₓZn_{y}O, ZrₓIn_{y}Zn_{z}O, HfₓIn_{y}Zn_{z}O, SnₓIn_{y}Zn_{z}O, AlₓSn_{y}In_{z}ZnₐO, SiₓIn_{y}Zn_{z}O, AlₓZn_{y}Sn_{z}O, GaₓZn_{y}Sn_{z}O, ZrₓZn_{y}Sn_{z}O, or a combination thereof.

Referring to FIGS. 3A, 3B, and 3C, each of the semiconductor patterns SP may include first and second dopant regions SD1, SD2 spaced apart from each other, and a channel region CH between the first and second dopant regions SD1, SD2, respectively. The first and second dopant regions SD1, SD2 of each semiconductor pattern SP may include a dopant (e.g., phosphorus or boron) of a first conductivity type.

Each of the first and second stacked structures ST1, ST2 may further include a first capping pattern CP1 and a second capping pattern CP2 disposed on opposite sides of each of the first and the second word lines WLa and WLb. The first capping pattern CP1 and the second capping pattern CP2 may extend in the first direction D1. The first capping pattern CP1 and the second capping pattern CP2 may be interposed between a pair of interlayer insulating patterns 140 adjacent to each other in the third direction D3 among the interlayer insulating patterns 140. The first and second capping patterns CP1 and CP2 may include an insulating material, and may include, for example, silicon oxide, silicon nitride, and/or silicon oxynitride.

The first capping pattern CP1 may be disposed between the first and second word lines WLa, WLb and data storage elements DS. The first capping pattern CP1 may surround the second dopant region SD2 corresponding to a second end of each of the semiconductor patterns SP. A portion of the first capping pattern CP1 may be disposed between sidewalls of the interlayer insulating patterns 140 and the capacitor dielectric layer CIL. A sidewall of first capping pattern CP1 may be misaligned with a first sidewall of the semiconductor patterns SP.

The second capping pattern CP2 may be disposed between the first and second word lines WLa, WLb and bit lines BLa, BLb. The second capping pattern CP2 may surround the first dopant region SD1 corresponding to a first end of each of the semiconductor patterns SP.

Each of the first and second stacked structures ST1, ST2 may include a first hard mask pattern 40 on the uppermost layer thereof. The first hard mask pattern 40 may include, for example, a silicon oxide film or a silicon nitride film.

A gate insulating layer GIL may be interposed between the semiconductor patterns SP and the first and second word lines WLa, WLb. The gate insulating layer GIL may cover the upper and lower surfaces and one sidewall of each of the first and second word lines WLa, WLb with a substantially uniform thickness.

The gate insulating layer GIL may extend in the second direction D2 to be interposed between each of the semiconductor patterns SP and the first capping pattern CP1, and between each of the semiconducting patterns SP and the second capping pattern CP2. Each of the semiconductor patterns SP may be spaced apart from the first capping pattern CP1 and the second capping pattern CP2 with the gate insulating layer GIL interposed therebetween. The gate insulating layer GIL may be interposed between the substrate 100 and the lowermost one of the first and second word lines WLa, WLb. A lowermost first capping pattern CP1 and a lowermost second capping pattern CP2 may be disposed on opposite sides of the lowermost first and second word lines WLa, WLb. The gate insulating layer GIL may extend between the substrate 100 and the lowermost first capping pattern CP1 and between the substrate 100 and the lowermost second capping pattern CP2.

The gate insulating layer GIL may include one single layer selected from a high-k dielectric layer, a silicon oxide layer, a silicon nitride layer, and a silicon oxynitride layer, or a combination thereof. For example, the high-k dielectric layer may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate.

The first and second bit lines BLa, BLb may extend in the third direction D3 perpendicular to the top surface of the substrate 100. The first and second bit lines BLa, BLb may intersect the first and second word lines WLa, WLb. The first bit lines BLa may be spaced apart from each other in the first direction D1. Buried insulating layer 160 may cover sidewalls of the first and second bit lines BLa, BLb. Isolation insulating patterns 161 may be respectively disposed between the first bit lines BL adjacent to each other in the first direction D1. The isolation insulating patterns 161 may extend in the third direction D3. The isolation insulating patterns 161 may be one of insulating materials, a silicon oxide layer, or a silicon oxynitride layer formed by using Spin-On-Glass (SOG) technology.

The second bit lines BLb may be spaced apart from the first bit lines BLa in the second direction D2, and may be spaced apart from each other in the first direction D1. The isolation insulating patterns 161 may be respectively disposed between the second bit lines BLb adjacent to each other in the first direction D1.

Each of the first and second bit lines BLa, BLb may contact the first sidewalls of the semiconductor patterns SP arranged along the third direction D3. In other words, each of the first and second bit lines BLa, BLb may be connected to the first dopant regions of the semiconductor patterns SP stacked along the third direction D3.

A lower isolation insulating layer 150 may be disposed between the first and second bit lines BLa, BLb and the substrate 100. The lower isolation insulating layer 150 may extend along the first direction D1 in parallel with the first and second stacked structures ST1, ST2.

The lower isolation insulating layer 150 may be one of insulating materials, a silicon oxide layer, or a silicon oxynitride layer formed using, for example, a Spin-On-Glass (SOG) technology. The lower isolation insulating layer 150 may be formed of, for example, a fluorine-doped oxide (FSG), a carbon-doped oxide, a silicon oxide, hydrogen silsesquioxane (HSQ; SiO:H), methyl silsesquioxane (MSQ; SiO; CH3), a-SiOC (SiOC:H), or the like.

Further, a third hard mask pattern 60 may be disposed on the first hard mask pattern 40 and the first and second bit lines BLa, BLb. The third hard mask pattern 60 may include, for example, a silicon oxide layer or a silicon nitride layer.

The data storage element DS may be connected to the second end of each semiconductor patterns SP. In some embodiments, the data storage element DS may be a capacitor, and the data storage element DS may include a storage node electrode SE, a plate electrode PE, and a capacitor dielectric layer CIL between the storage node electrode SE and the plate electrode PE.

Storage node electrodes SE may contact, respectively, the second sidewalls of each of the semiconductor patterns SP. The storage node electrodes SE may be provided, respectively, at substantially the same level as the semiconductor patterns SP. In other words, a plurality of the storage node electrodes SE may be stacked in the third direction D3 and may have a long axis in the second direction D2.

The storage node electrodes SE may be spaced apart from each other in the first direction D1 and the third direction D3. The storage node electrodes SE may be spaced apart from the first and second bit lines BLa, BLb in the second direction D2. The storage node electrode SE may have a pillar shape extending along the second direction D2.

The storage node electrodes SE may include at least one of doped silicon (Si), doped silicon germanium (SiGe), a metal (e.g., Ti, Mo, W, Cu, Al, Ta, Ru, Ir, Co, Pt, Au, Ag, etc.), a metal nitride (e.g., a nitride of Ti, Mo, W, Cu, Al. Ta, Ru, Ir, Co, Pt, Au, Ag, etc.), titanium silicon nitride (for example, TiSiN), titanium aluminum nitride (for example, TiAlN) and tantalum aluminum nitrides (for example, TaAlN), etc.), a conductive oxide (for example, PtO, RuO₂, IrO2, SRO (SrRuO₃), BSRO ((Ba,Sr)RuO₃) CRO (CaRuO₃) LSCo), or a metal silicide.

The capacitor dielectric layer CIL may conformally cover the surfaces of the storage node electrode SE. The capacitor dielectric layer CIL may extend between the storage node electrode SE along the first direction D1 and the third direction D3. The capacitor dielectric layer CIL may extend between the substrate 100 and the plate electrode PE along the second direction D2. The plate electrode PE may be spaced apart from the substrate 100 with the dielectric layer CIL interposed therebetween. The capacitor dielectric layer CIL may include, for example, at least one of a metal oxide such as HfO₂, ZrO₂, Al₂O₃, La₂O₃, Ta₂O₃, and TiO₂, or a dielectric material having a perovskite structure such as SrTiO₃ (STO), (Ba,Sr)TiO₃(BST), BaTiO₃, PZT, and PLZT.

The plate electrode PE may cover the capacitor dielectric layer CIL with a uniform thickness. The plate electrode PE may include at least one of impurity-doped silicon (Si), impurity-doped silicon germanium (SiGe), a metal (e.g., Ti, Mo, W, Cu, Al, Ta, Ru, Ir, Co, Pt, Au, Ag, etc.), a metal nitride (e.g., a nitride of Ti, Mo, W, Cu, Al. Ta, Ru, Ir, Co, pt, Au, Ag, etc.), titanium silicon nitride (for example, TiSiN), titanium aluminum nitride (such as TiAlN) and tantalum aluminum nitrides (such as TaAlN), a conductive oxide (for example, PtO, RuO₂, IrO₂, SRO (SrRuO₃), BSRO ((Ba,Sr)RuO₃), CRO (CaRuO₃), LSCo, or a metal silicide.

According to some embodiments, contact patterns NCP may be disposed between the storage node electrodes SE and the second sidewalls of the semiconductor patterns SP, respectively. The contact pattern NCP may include one of doped silicon (Si) or doped silicon germanium (SiGe). The dopant concentration of the contact pattern NCP may be greater than that of the first and second dopant regions SD1 and SD2 in the semiconductor pattern SP. The contact pattern NCP may have a first sidewall recessed toward the semiconductor patterns SP.

In detail, referring to FIG. 3A, the contact pattern NCP may include a contact portion CT contacting the second sidewall of the semiconductor patterns SP and a horizontal portion HP extended from the contact portion CT in the second direction D2 to define a recess region.

In some embodiments, in the third direction D3, each of the semiconductor patterns SP may have a first thickness t1, and the storage node electrode SE may have a second thickness t2 that is greater than the first thickness t1. In addition, in the third direction D3, the thickness of the horizontal portion of the contact pattern NCP may be less than about one half (1/2) of the first thickness t1 of each of the semiconductor patterns SP. For example, the thickness of the horizontal portion of the contact pattern NCP may be about 1 nm to 10 nm.

The contact portion CT of the contact pattern NCP may have a first length in the third direction D3, and the first length may be substantially equal to the first thickness t1 of each of the semiconductor patterns SP. The distance between the top surface and the bottom surface of the horizontal portion HP of the contact pattern NCP may be greater than the first length of the contact portion CT and may be substantially equal to the second thickness t2 of the storage node electrode SE. The top surface of the storage node electrode SE may be substantially coplanar with the top surface of the horizontal portion HP of the contact pattern NCP, and the bottom surface of the storage node electrode SE may be substantially coplanar with the bottom surface of the horizontal portions HP of the contact pattern NCP.

According to some embodiments, a silicide pattern SC may be disposed between the contact pattern NCP and the storage node electrode SE. The silicide pattern SC may include, for example, at least one of cobalt silicide, nickel silicide, tungsten silicide, or tantalum silicide. However, the disclosure is not limited thereto, and the metal silicide material may be variously changed.

The silicide pattern SC may have a substantially uniform thickness on the surface of the contact pattern NCP and may have a recess region recessed toward each of the semiconductor patterns SP. A portion of the storage node electrode SE may be disposed in the recess region of the silicide pattern SC.

Meanwhile, referring to FIG. 3B, the contact pattern NCP may include a contact portion CT contacting the second sidewall of each of the semiconductor patterns SP, a first horizontal portion HP1 extended from the contact portion CT in the second direction D2 to define a first recess region between portions of the gate insulating layer GIL, and a second horizontal portion HP2 extended from the first horizontal portion HP1 in the second direction D2 to define a second recess region.

In some embodiments, in the third direction D3, the distance between a top surface and a bottom surface of the first horizontal portion HP1 may be substantially equal to the first thickness t1 of each of the semiconductor patterns SP, and the distance between a bottom surface and a top surface of the second horizontal portion HP2 may be substantially equal to the second thickness t2 of the storage node electrode SE.

The silicide pattern SC contacting the contact pattern NCP may fill the first recess region defined by the first horizontal portion HP1 of the contact pattern NPC and may be disposed in the second recess region defined by the second horizontal portion HP2 of the contact pattern NCP. The silicide pattern SC may have a side surface recessed toward each of the semiconductor patterns SP in the second horizontal portion HP2 of the contact pattern NCP.

Referring to FIG. 3C, in the third direction D3, the first thickness t1 of each of the semiconductor patterns SP may be substantially equal to the second thickness t2 of the storage node electrode SE . In addition, the contact pattern NCP may include a contact portion CT and a horizontal portion HP, and may have a recess region defined by the contact portion CT and the horizontal portion HP, as described above. The recess region of the contact pattern NCP may be filled with the silicide pattern SC, and the silicide pattern SC may have flat side surfaces.

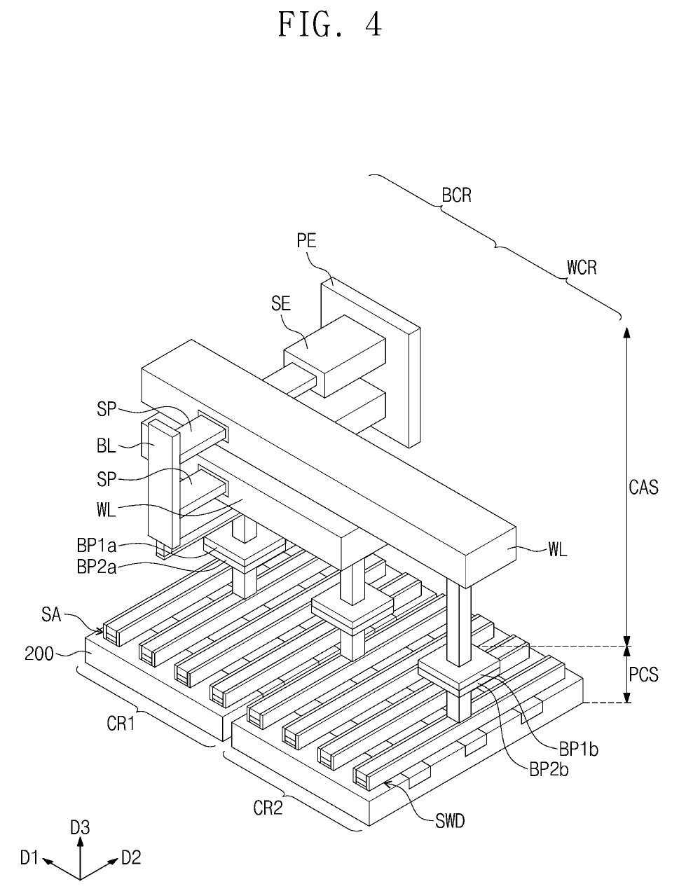

FIG. 4 is a perspective view illustrating a portion of a semiconductor memory device according to embodiments of the disclosure.

Referring to FIG. 4, a semiconductor memory device may include a cell array structure CAS and a peripheral circuit structure PCS on the cell array structure CAS.

In some embodiments, the semiconductor memory device may have a chip-to- chip (C2C) structure. The C2C structure may mean a structure in which an upper chip includes the cell array structure CAS is fabricated on a first wafer, a lower chip includes the peripheral circuit structure PCS is fabricated on a second wafer different from the first wafer, and the upper chip and the lower chip are connected to each other in a bonding manner. For example, the bonding manner may mean a manner in which bonding metal formed on an uppermost metal layer of the upper chip and bonding metal formed on an uppermost metal layer of the lower chip are electrically connected to each other. For example, when the bonding metal is formed of copper (Cu), the bonding manner may be a Cu-to-Cu bonding manner. The bonding metal may be formed of aluminum (Al) or tungsten (W).

The cell array structure CAS may include a first region BCR (or a bit line connection region) and a second region WCR (or a word line connection region).

The cell array structure CAS may include word lines WL, bit lines BL, and first bonding pads BP1a, BP1b.

The word lines WL may extend along the first direction D1 and may be vertically stacked along the third direction D3. The word lines WL may extend from the first region BCR to the second region WCR, and the bit lines BL may be provided in the first region BCR. Each of the word lines WL may include a pad portion connected to a cell contact plug in the second region WCR. The word lines WL may be stacked to have a stepped structure in the second region WCR. The pad portions of the word lines WL may be located at different positions horizontally and vertically.

According to some embodiments, each of the word lines WL may have a structure (i.e., a gate all around structure) completely surrounding the semiconductor patterns SP. Alternatively, each of the word lines WL may have a double gate structure crossing upper and lower surfaces of the semiconductor patterns SP.

The bit lines BL may extend along the third direction D3 and may be connected to the semiconductor patterns SP stacked in the third direction D3.

A first end of each of the semiconductor patterns SP may be connected to a bit line BL, and a second end of each of the semiconductor patterns SP may be connected to a storage node electrode SE. In addition, the contact pattern NCP and the silicide pattern SC shown in FIGS. 3A, 3B, and 3C, may be disposed between the second end of each of the semiconductor patterns SP and the storage node electrode SE.

In some embodiments of the disclosure, the first bonding pads BP1a, BP1b of the cell array structure CAS may include a first upper bonding pad BP1a provided in the first region BCR and a second upper bonding pad BP1b provided in the word line connection regions WCR.

The first upper bonding pad BP1a may be electrically connected to the bit line BL through a conductive line and a contact plug, and the second upper bonding pad BP1b may be connected to the pad portions of the word lines WL through conductive lines and cell contact plugs.

The peripheral circuit structure PCS may include a semiconductor substrate 200, a sense amplifier SA, a sub-word line driver SWD, a peripheral circuit, and second bonding pads BP2a, BP2b on the semiconductor substrate 200.

In detail, the semiconductor substrate 200 of the peripheral circuit structure PCS may include a first core region CR1 and a second core region CR2. The first and second core regions CR1, CR2 may vertically overlap the first region BCR and the second region WCR, respectively.

The sense amplifier SA may be provided on the semiconductor substrate 200 of the first core region CR1. The sub-word line driver SWD may be provided on the semiconductor substrate 200 of the second core region CR2.

The second bonding pads BP2a, BP2b of the peripheral circuit structure PCS may include a first lower bonding pad BP2a provided in the first core region CR1 and a second lower bonding pad BP1b provided in the second core region CR2.

The first lower bonding pad BP2a may be electrically connected to the sense amplifier SA through a conductive line and a contact plug. The second lower bonding pad BP2b may be electrically connected to the sub-word line driver SWD through a conductive line and a contact plug.

In some embodiments, the first and second lower bonding pads BP2a, BP2b may be directly connected to the first and second upper bonding pads BP1a, BP1b, respectively. The first and second upper bonding pads BP1a, BP1b and the first and second lower bonding pads BP2a, BP2b may include the same metal material, and may have substantially the same size or area. The first and second upper bonding pads BP1a, BP1b and the first and second lower bonding pads BP2a, BP2b may include, for example, copper (Cu), aluminum (Al), nickel (Ni), cobalt (Co), tungsten (W), titanium (Ti), tin (Sn), or an alloy thereof.

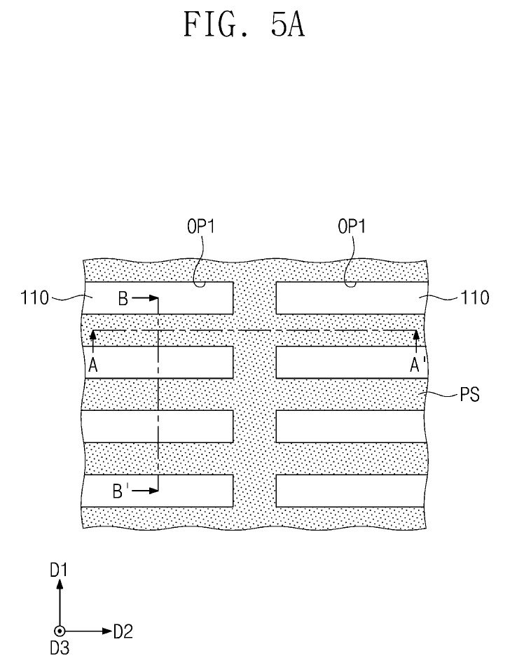

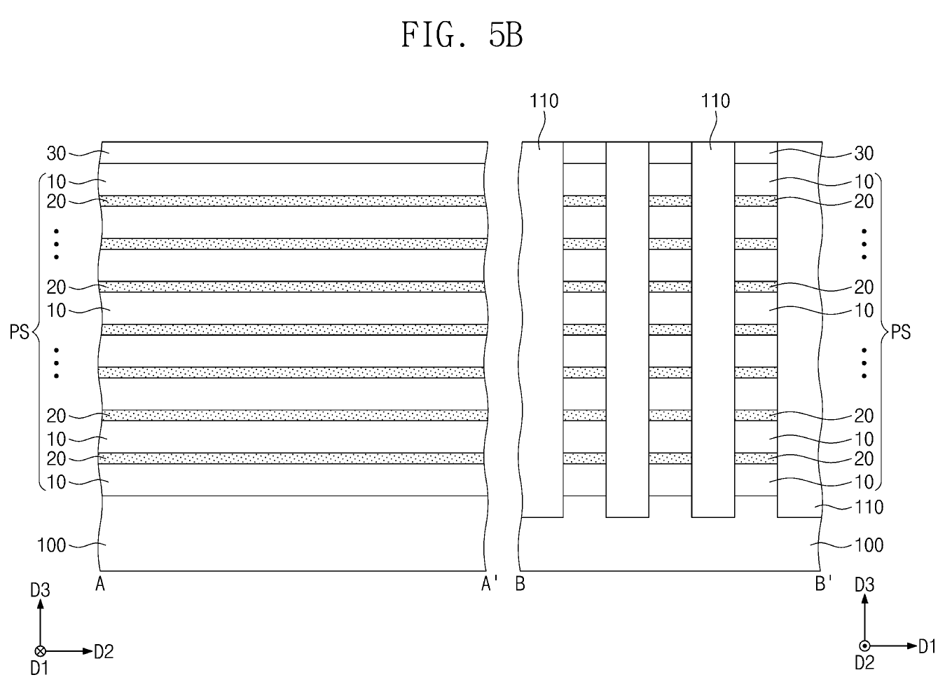

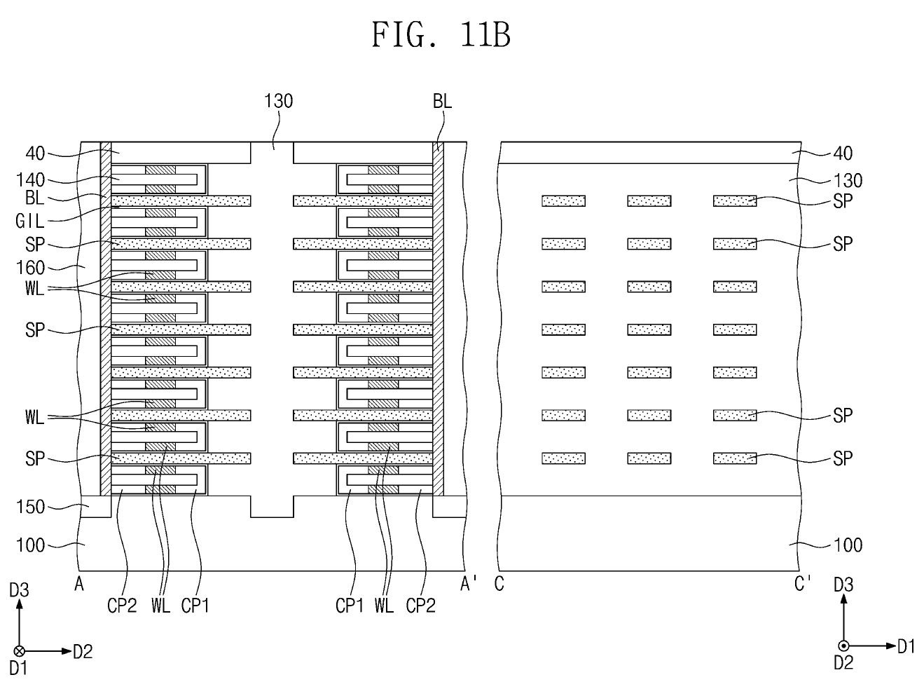

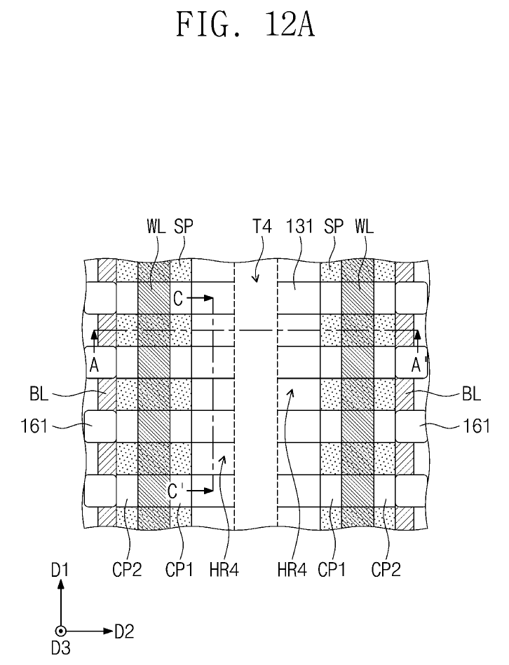

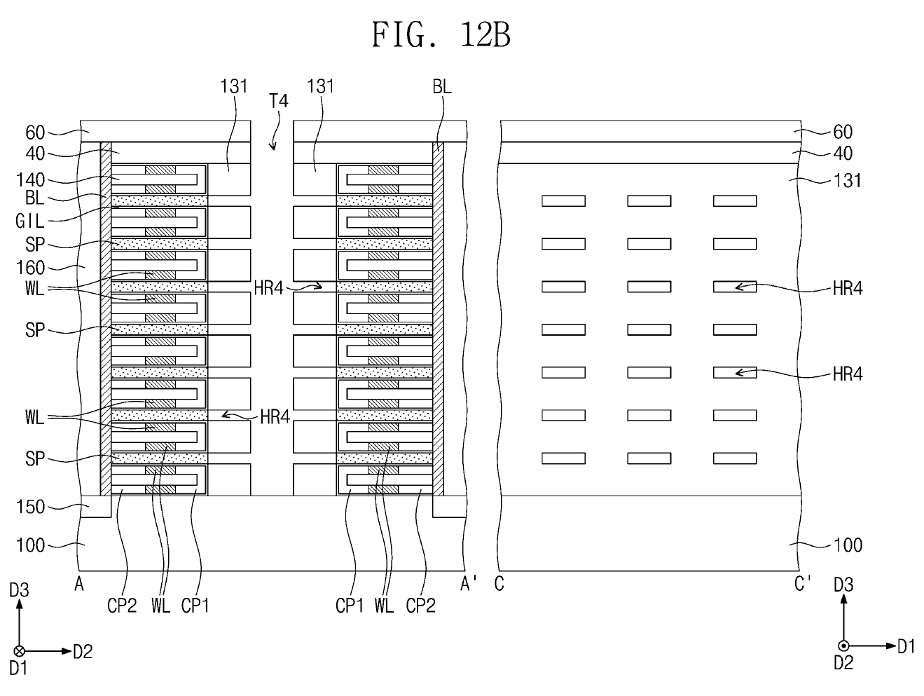

FIGS. 5A, 6A, 7A, 8A, 9A 10A, 11A, 12A, and 13A, are plan views to illustrate a method for manufacturing a semiconductor memory device according to embodiments of the disclosure. FIGS. 5B, 6B, 7B, 8B, 9B and 10B are cross-sectional views taken along a line A-A′ and a line B-B′ of FIGS. 5A, 6A, 7A, 8A, 9A and 10A. FIGS. 11B, 12B, and 13B, are cross-sectional views taken along a line A-A′ and a line C-C′ of FIGS. 11A, 12A, and 13A.

Referring to FIGS. 5A and 5B, a thin layer structure PS may be formed on a substrate 100.

The substrate 100 may include a material having semiconductor characteristics (e.g., a silicon wafer). Alternatively, instead of the substrate 100, an insulating material (e.g., glass), a semiconductor material covered with the insulating material, or a conductive material may be used as the substrate.

The thin layer structure PS may include sacrificial layers 10 and semiconductor layers 20 alternately stacked on the substrate 100.

The sacrificial layers 10 may be formed of a material having an etching selectivity with respect to the semiconductor layers 20. The sacrificial layers 10 may be formed of, for example, at least one of silicon germanium, a silicon oxide layer, a silicon nitride layer, or a silicon oxynitride layer. For example, the sacrificial layers 10 may be a semiconductor material, for example, a silicon germanium layer. When the thin layer structure PS is formed, a thickness of each sacrificial layer 10 may be greater than that of each semiconductor layer 20.

The semiconductor layers 20 may include, for example, silicon, germanium, silicon-germanium, or Indium Gallium Zinc Oxide (IGZO). In some embodiments, the semiconductor layers 20 may include the same semiconductor material as the substrate 100. For example, the semiconductor layers 20 may be a single-crystalline silicon layer or a poly-crystalline silicon layer.

According to some embodiments, the sacrificial layers 10 and the semiconductor layers 20 may be formed by performing an epitaxial growth process. The semiconductor layers 20 may be single-crystalline silicon layers, and the sacrificial layers 10 may be silicon germanium layers having a super lattice structure.

An upper insulating layer 30 covering the uppermost sacrificial layer 10 may be formed on the thin layer structure PS. The upper insulating layer 30 may be formed of an insulating material having an etching selectivity with respect to the sacrificial layers 10 and the semiconductor layers 20. For example, the upper insulating layer 30 may be a silicon oxide layer.

After the thin layer structure PS is formed, line holes OP1 penetrating the thin layer structure PS may be formed.

The line holes OP1 may be formed to penetrate the sacrificial layers 10 and the semiconductor layers 20. The line holes OP1 may be spaced apart from each other in the first direction D1 and the second direction D2. Each line hole OP1 may extend along the third direction D3 to penetrate the sacrificial layers 10 and the semiconductor layers 20, and may expose the top surface of the substrate 100. The line holes OP1 may include a first row including the line holes OP1, which are spaced apart from each other in the first direction D1, and a second row including the line holes OP1, which are spaced apart from one another in the first direction D1, and the second row of the line holes OP1 may be spaced apart from the first row of the line hole OP1 in the second direction D2. The line holes OP1 in the first row may be aligned with the line holes OP1 in the second row in the second direction D2. First portions of the sacrificial layers 10 and the semiconductor layers 20 may extend along the first direction D1 between the first row of the line holes OP1 and the second row of the line holes OP1. Second portions of the sacrificial layers 10 and the semiconductor layers 20 may extend along the second direction D2 between the line holes OP1 of the first row and between the line holes OP1 of the second row.

Thereafter, first filling patterns 110 may be respectively filled in the line holes OP1.

The first filling patterns 110 may contact the substrate 100. The first filling patterns 110 may be one of insulating materials, a silicon oxide layer, or a silicon oxynitride layer formed by using a spin on glass (SOG) technology. The first filling patterns 110 may be formed by depositing a separation insulating layer to fill the line holes OP1, and then planarizing the separation insulating layer to expose a top surface of the upper insulating layer 30.

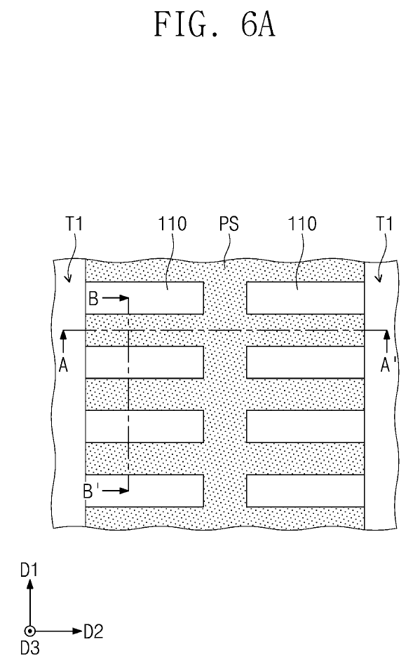

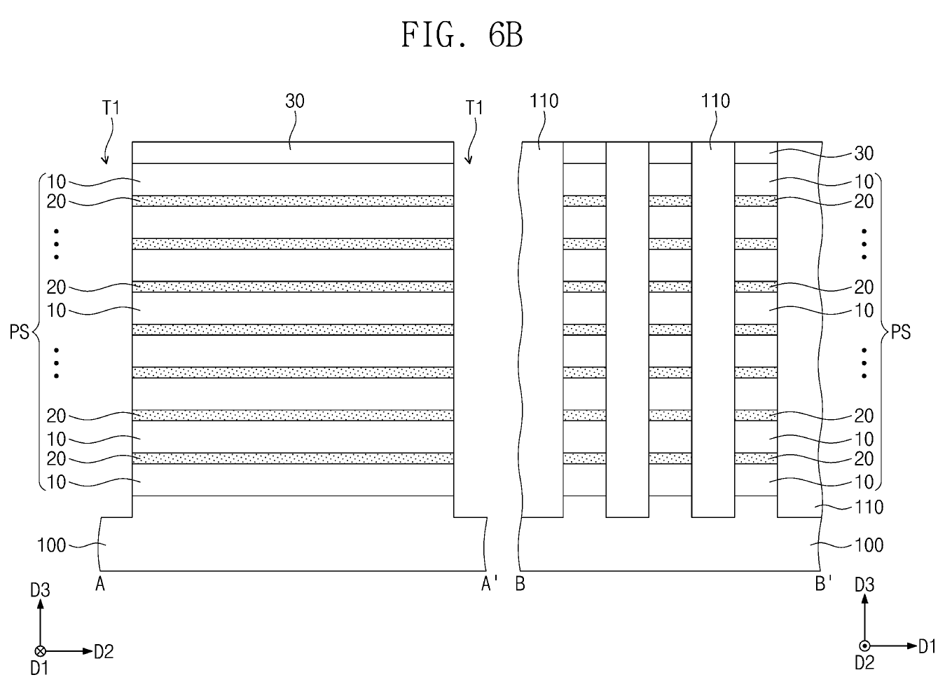

Referring to FIGS. 6A and 6B, first trenches T1 extending along the first direction D1 and penetrating the thin layer structure PS may be formed. The first trenches T1 may be spaced apart from each other in the second direction D2. The first trenches T1 may expose sidewalls of the sacrificial layers 10 and sidewalls of the semiconductor layers 20 and sidewalls of first filling patterns 110.

Forming the first trenches T1 may include forming a mask pattern having openings corresponding to the first trenches T1 on the thin layer structure PS, and anisotropically etching the thin layer structure PS by using the mask pattern as an etching mask. The first trenches T1 may expose the top surface of the substrate 100, and a recess region may be formed by recessing the top surface of the substrate 100 under the first trenches T1, by an over-etching during an anisotropic etching.

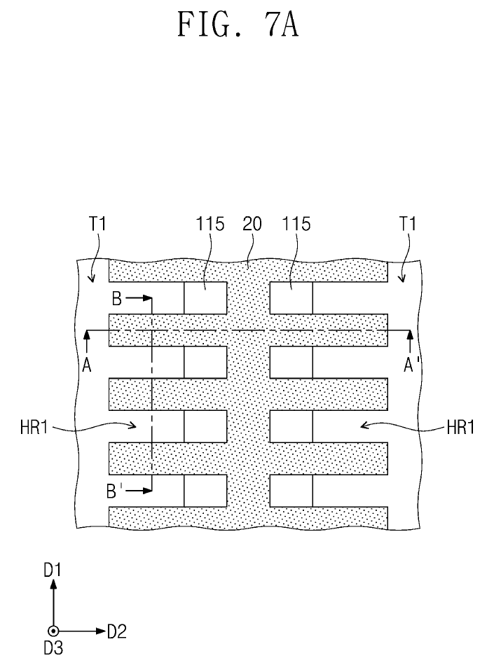

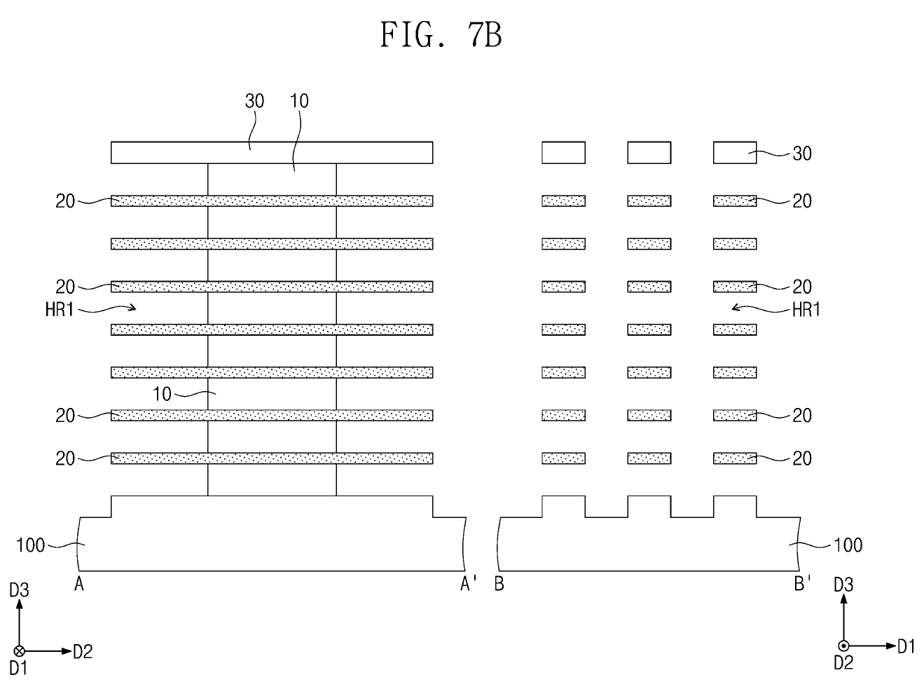

Referring to FIGS. 7A and 7B, side surfaces of the sacrificial layers 10 and the first filling patterns 110 exposed by the first trenches T1 may be laterally recessed. Therefore, first horizontal regions HR1 may be formed. The first horizontal regions HR1 may be interposed between the semiconductor layers 20 spaced apart from each other in the third direction D3, and may extend between the semiconductor layers 20 spaced apart from one another in the first direction D1. The lowermost one of the first horizontal regions HR1 may be interposed between the lowermost one of the semiconductor layers 20 and the substrate 100, and may expose the top surface of the substrate 100.

When the first horizontal regions HR1 are formed, portions of the first filling patterns 110 may remain to form first residual filling patterns 115.

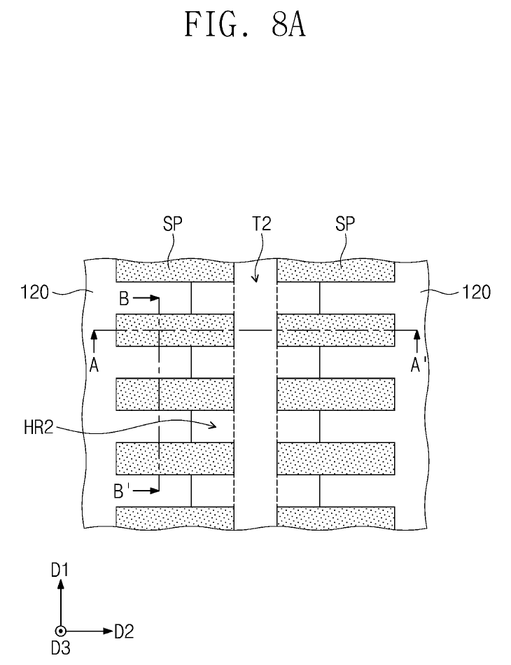

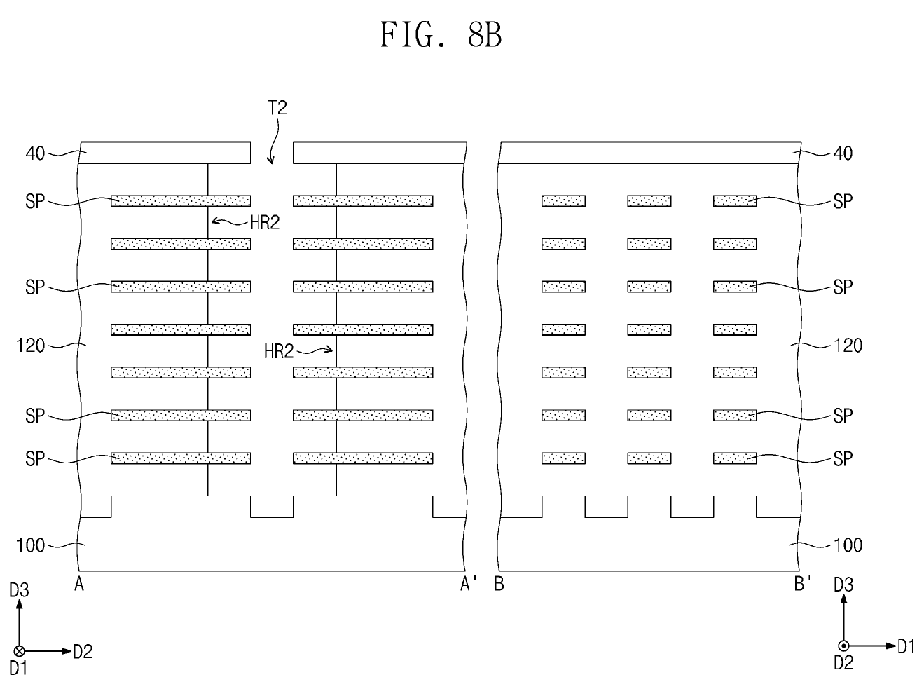

Referring to FIGS. 8A and 8B, second filling patterns 120 may be formed to fill the first horizontal regions HR1 and the first trenches T1 (refer to FIG. 7A). The second filling patterns 120 may include an insulating material, and may include, for example, silicon oxide, silicon nitride, and/or silicon oxynitride. Then, the upper insulating layer 30 may be removed, and a first hard mask pattern 40 may be formed.

After the first hard mask pattern 40 is formed, an anisotropic etching process may be performed on the thin layer structure PS by using the first hard mask pattern 40 as an etching mask. Therefore, a second trench T2 extending along the first direction D1 may be formed. The second trench T2 may penetrate the thin layer structure PS to expose the top surface of the substrate 100. The semiconductor layers 20 may be separated into a plurality of semiconductor patterns SP spaced apart from each other in the first direction D1, the second direction D2, and the third direction D3 by the second trench T2. Each of the semiconductor patterns SP may have a bar shape having a long axis in the second direction D2. The second trench T2 may be formed between a pair of first trenches T1 (refer to FIG. 7A) and may extend along the first direction D1 to expose sidewalls of the first residual filling patterns 115.

After forming the second trench T2, the sacrificial layers 10 and the first residual filling patterns 115 may be removed by laterally recessing the side surfaces of the sacrificial layers 10 and the first residual filling patterns 115 exposed by the second trench T2. Therefore, second horizontal regions HR2 may be formed. The second horizontal regions HR2 may be interposed between the semiconductor layers 20 spaced apart from each other in the third direction D3, and may extend between the semiconductor layers 20 spaced apart from each other in the first direction D1. The lowermost one of the second horizontal regions HR2 may be interposed between the lowermost one of the semiconductor patterns SP and the substrate 100, and may expose the top surface of the substrate 100. The second horizontal regions HR2 may expose side surfaces of the second filling patterns 120.

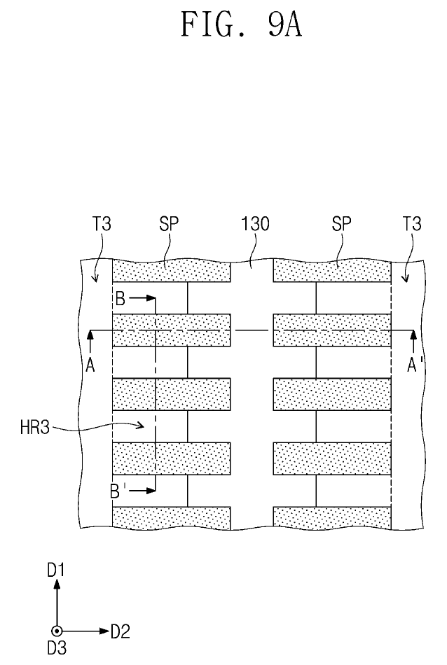

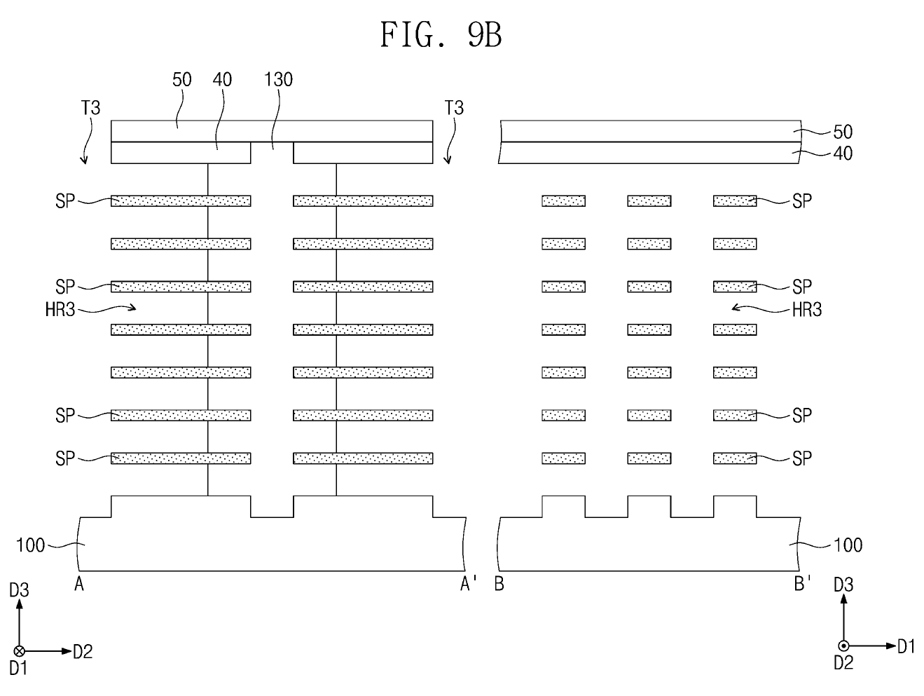

Referring to FIGS. 9A and 9B, a third filling pattern 130 may be formed to fill the second trench T2 and the second horizontal regions HR2. The third filling pattern 130 may include an insulating material, and may include, for example, silicon oxide, silicon nitride, and/or silicon oxynitride.

Thereafter, a second hard mask pattern 50 may be formed on the first hard mask pattern 40, and an anisotropic etching process on the second filling patterns 120 may be performed by using the second hard mask pattern 50 as an etching mask. Accordingly, third trenches T3 may be formed to penetrate the second filling patterns 120 and to expose the substrate 100. The third trenches T3 may extend along the first direction D1 and may be spaced apart from each other in the second direction D2. The third trenches T3 may expose the first sidewalls of the semiconductor patterns SP.

After forming the third trenches T3, the second filling patterns 120 may be removed to form third horizontal regions HR3 between the semiconductor patterns SP adjacent to each other, respectively. The third horizontal regions HR3 may be formed by isotropically etching the second filling pattern 120 by using an etching recipe having an etching selectivity with respect to the semiconductor patterns SP and the second filling patterns 120. The third horizontal regions HR3 may extend along the first direction D1 between vertically adjacent semiconductor patterns SP.

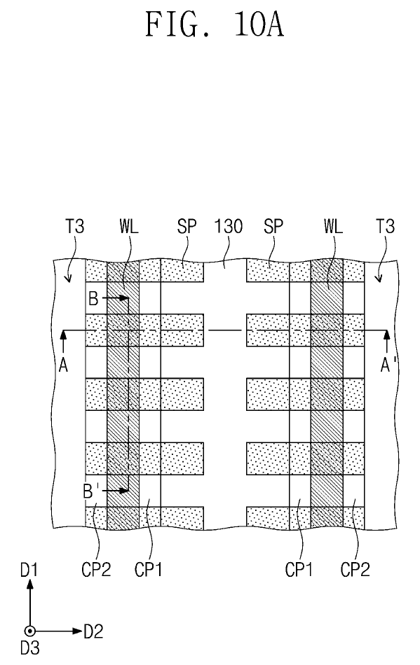

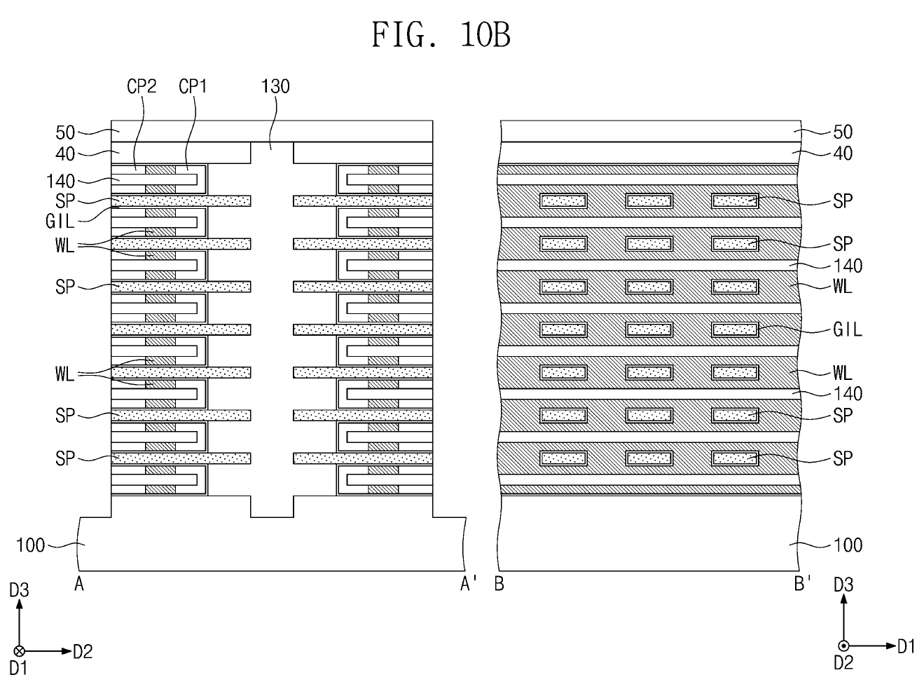

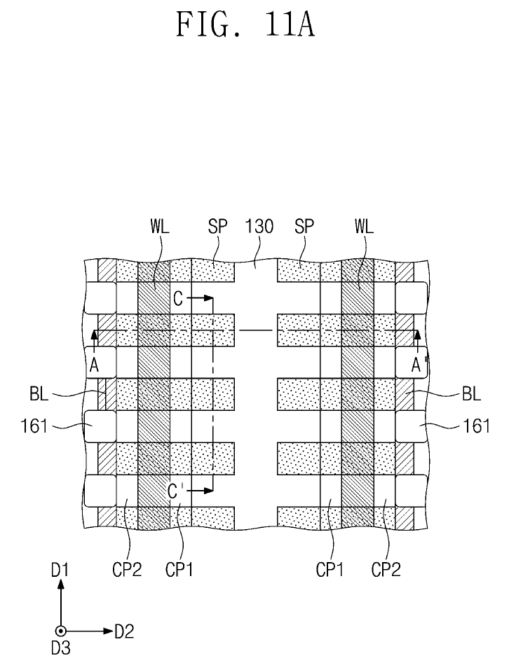

Referring to FIGS. 10A and 10B, a gate insulating layer GIL, a first capping pattern CP1, word lines WL, and a second capping pattern CP2 may be formed in the third horizontal regions HR3.

In detail, after the third horizontal regions HR3 are formed, the gate insulating layer GIL may be formed to conformally cover the surfaces of the semiconductor patterns SP exposed to the third horizontal regions HR3. The gate insulating layer GIL may extend to conformally cover a side surface of the third filling pattern 130 between the semiconductor patterns SP and the top surface of the substrate 100.

Thereafter, a capping insulating layer may be deposited on the gate insulating layer GIL, and may be formed to conformally cover inner surfaces of the third horizontal regions HR3. The capping insulating layer may extend to conformally cover a side surface of the third filling pattern 130 between the semiconductor patterns SP.

The capping insulating layer may be deposited to have a thickness less than one half of a vertical thickness of the third horizontal region HR3. Therefore, the capping insulating layer may define a gap region in each of the third horizontal regions HR3 in which the gate insulating layer GIL is formed, and an interlayer insulating layer may be filled in the gap region. The capping insulating layer may be formed of, for example, at least one of a silicon oxide layer, a silicon nitride layer, or a silicon oxynitride layer.

After the interlayer insulating layer is formed, portions of the interlayer insulating layer disposed in the third trenches T3 may be etched to form interlayer insulating patterns 140. Forming the interlayer insulating patterns 140 may include isotropically etching the interlayer insulating layer to expose the capping insulating layer. The interlayer insulating patterns 140 may be vertically separated from each other by the isotropic etching process. The interlayer insulating patterns 140 may be formed of an insulating material having an etching selectivity with respect to the third filling pattern 130 and the substrate 100. In an embodiment, the interlayer insulating patterns 140 may be silicon oxide.

After the interlayer insulating patterns 140 are formed, the first capping pattern CP1 may be respectively formed in the third horizontal regions HR3 by performing an isotropic etching process on a portion of the capping insulating layer. The first capping pattern CP1 may extend along the first direction D1 and surround a portion of each of the semiconductor patterns SP. The first capping pattern CP1 may extend between the side surfaces of the third filling pattern 130 and the interlayer insulating patterns 140.

By performing an isotropic etching process on a portion of the capping insulating layer, the side surfaces of the capping insulation layer may be laterally recessed to form empty regions, and the conductive layer may be formed to fill the empty regions.

Forming the conductive layer may include forming a conductive layer that fills the empty regions and fills a portion of each of the third trenches T3, and removing a portion of the conductive layer in each of the third recesses T3. Subsequently, side surfaces of the conductive layer exposed by each of the third trenches T3 may be laterally recessed, and portions of the conductive layer may remain in the third horizontal regions HR3. Therefore, word lines WL adjacent to the first capping pattern CP1 may be formed in the third horizontal regions HR3. Here, sidewalls of the word lines WL may be laterally recessed from the first sidewalls of the semiconductor patterns SP. The word lines WL may be filled in portions of the third horizontal regions HR3. The word lines WL may surround central portions (i.e., channel portions) of the semiconductor patterns SP and may extend along the first direction D1. The word lines WL may have a structure (i.e., a gate-all-around structure) that completely surrounds the central portions (i.e., channel portions) of the semiconductor patterns SP. Alternatively, each word line WL may have a double gate structure provided on the top and bottom surfaces of each of the semiconductor patterns SP.

The first dopant regions SD1 may be formed in the semiconductor patterns SP. The first dopant regions SD1 may be formed in exposed portions of the semiconductor patterns SP. The second capping pattern CP2 may be formed to fill the third horizontal regions HR3 in which the word lines WL are formed. The second capping pattern CP2 may extend in the first direction D1 and surround a portion of each of the semiconductor patterns SP. The gate insulating layer GIL may be interposed between each of the semiconductor patterns SP and the word lines WL, and may extend between each of the semiconductor patterns SP and the first capping pattern CP1, and between each of the semiconductor patterns SP and the second capping pattern CP2.

Referring to FIGS. 11A and 11B, after the second capping pattern CP2 is formed, a lower isolation insulating layer 150 may be formed in a lower portion of the third trenches T3. The lower isolation insulating layer 150 may extend along the first direction D1. The lower isolation insulating layer 150 may include an insulating material such as silicon oxide, silicon nitride, or silicon oxynitride.

The lower isolation insulating layer 150 may be formed of, for example, a fluorine-doped oxide (FSG), a carbon-doped oxide, a silicon oxide, hydrogen silsesquioxane (HSQ; SiO:H), methyl silsesquioxane (MSQ; SiO; CH3), a-SiOC (SiOC:H), or the like. For example, the lower isolation insulating layer 150 may be formed by spin-coating SiOC having a low viscosity.

Bit lines BL may be formed in each of the third trenches T3. The second hard mask pattern 50 may be removed before or after forming the bit lines BL.

Forming the bit lines BL may include sequentially depositing a conductive layer and a buried insulating layer 160 in the third trenches T3, performing a planarization process on the conductive layer and the buried insulating layer 160, and patterning the conductive layer.

The bit lines BL may be separated from each other in the first direction D1. After the bit lines BL are formed, isolation insulating patterns 161 may be formed between the bit lines BL in the first direction D1. Each of the bit lines BL may contact the first dopant regions of the semiconductor patterns SP. The bit lines BL may include at least one of silicon doped with an impurity, metal materials, metal nitrides, or metal silicides. For example, the bit lines BL may include doped polysilicon, a tantalum nitride layer, or tungsten.

Referring to FIGS. 12A and 12B, the third hard mask pattern 60 may be formed to cover the first hard mask pattern 40.

A fourth trench T4 may be formed by performing an anisotropic etching process by using the third hard mask pattern 60 as an etching mask. The fourth trench T4 may penetrate the third filling pattern 130 to expose the substrate 100. The fourth trench T4 may extend in the first direction D1. When the fourth trench T4 is formed, third residual filling patterns 131 may be formed between vertically adjacent semiconductor patterns SP.

After the fourth trench T4 are formed, portions of the semiconductor patterns SP exposed by the fourth trench T4 may be laterally recessed. in other words, the portions of the semiconductor patterns SP may be isotropically etched, and the length of the semiconductor patterns SP may be reduced in the second direction D2. In addition, fourth horizontal regions HR4 may be formed between vertically adjacent third residual filling patterns 131.

Dopants (e.g., phosphorus or boron) of the first conductivity type may be doped in portions of the semiconductor patterns SP exposed in the fourth horizontal regions HR4. Accordingly, second dopant regions SD2 (refer to FIG. 1B) may be formed in the semiconductor patterns SP.

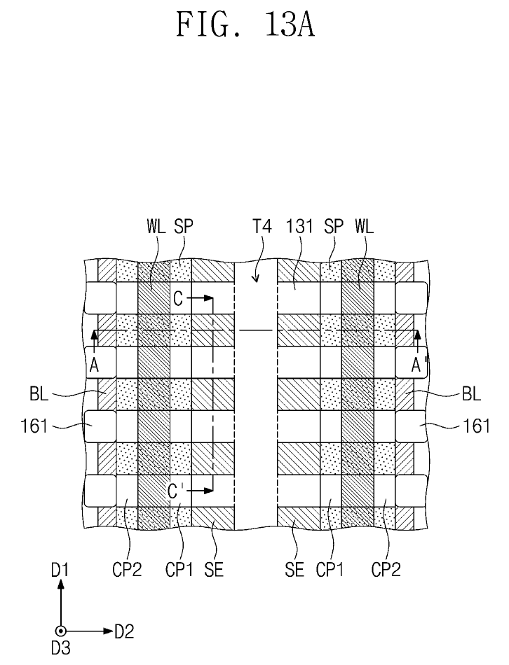

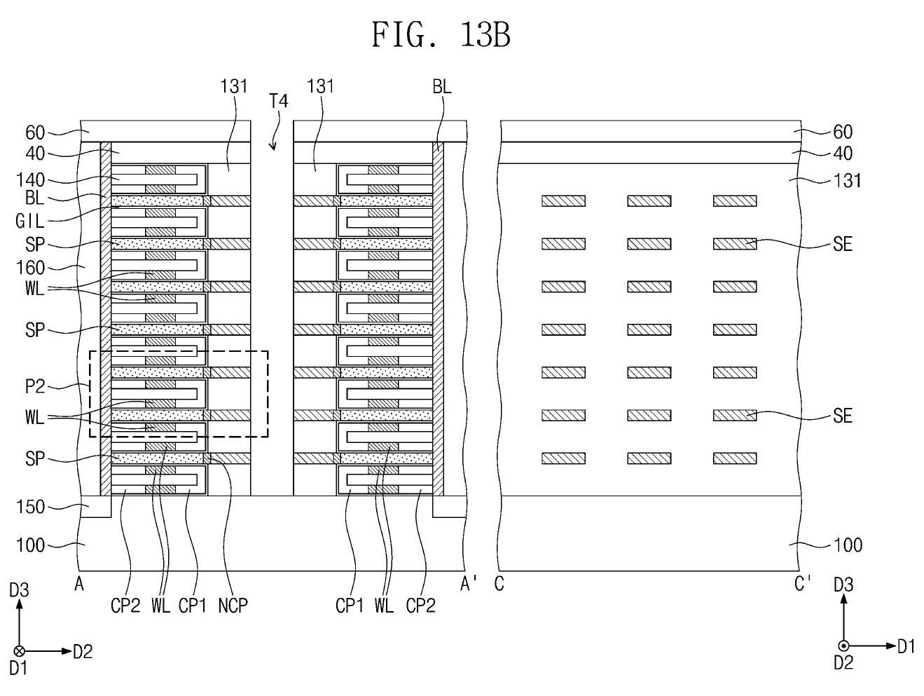

Referring to FIGS. 13A and 13B, contact patterns NCP contacting an end of each of the semiconductor patterns SP and storage node electrodes SE on the contact patterns NCP may be formed in the fourth horizontal regions HR4.

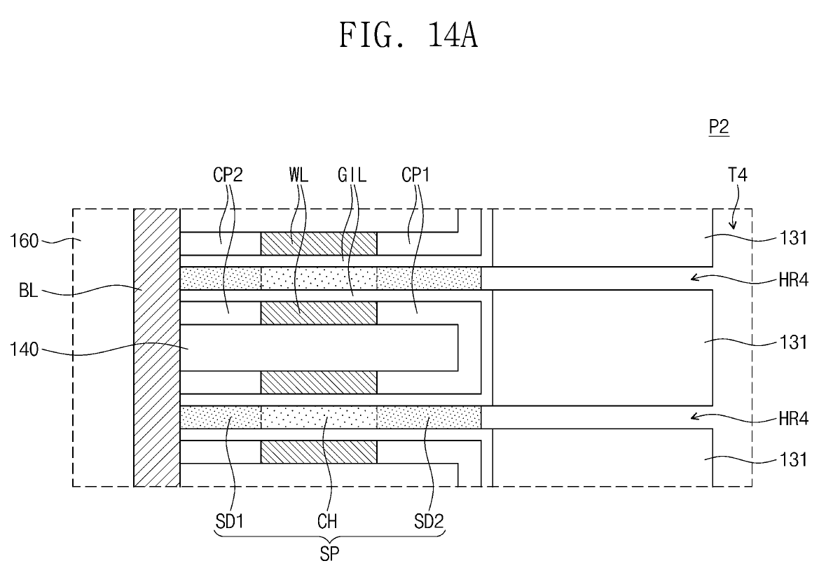

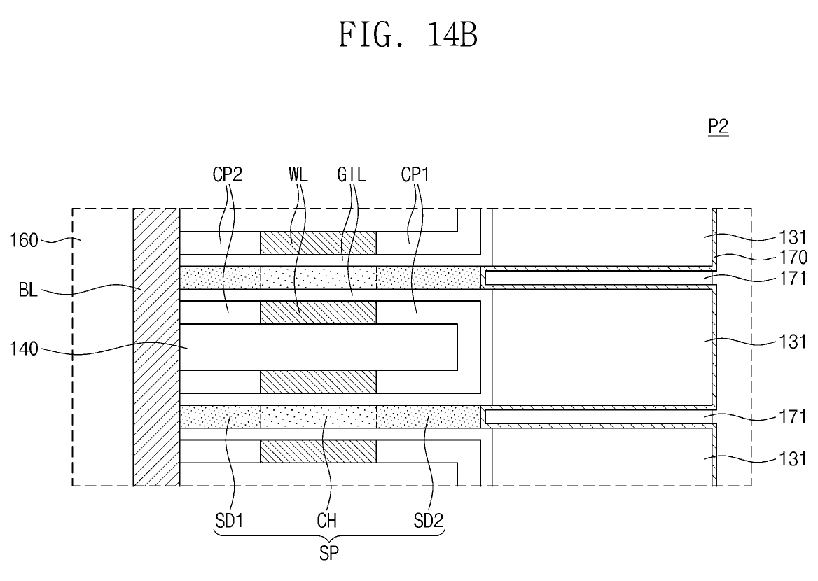

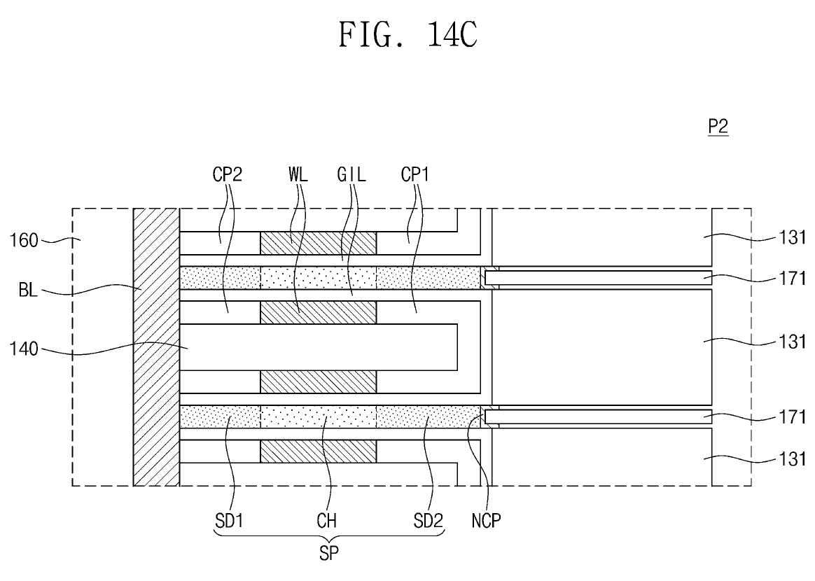

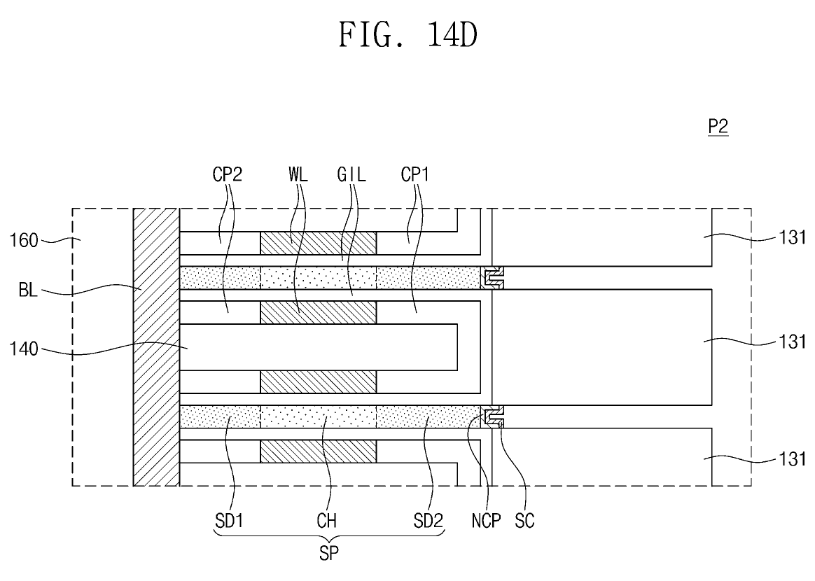

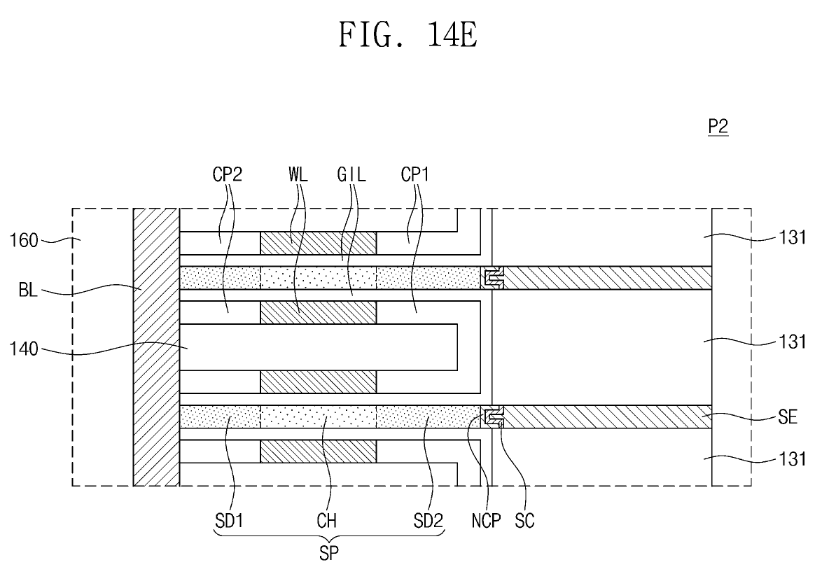

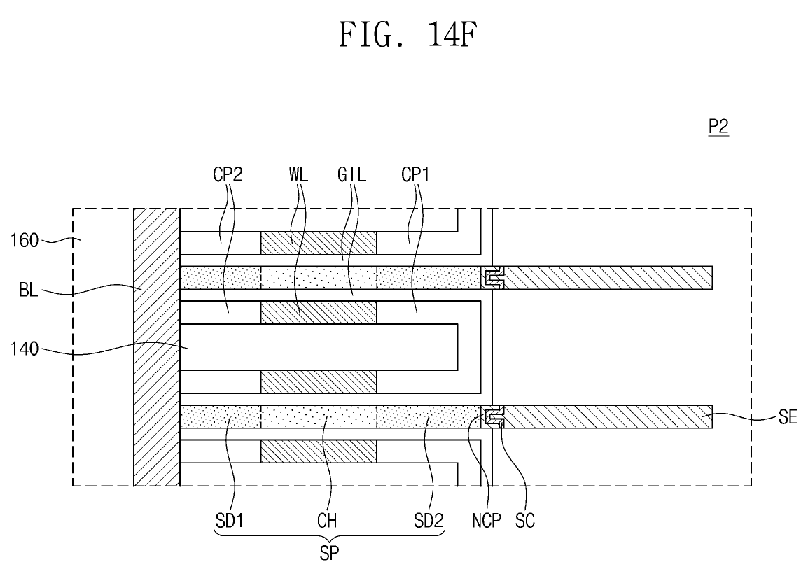

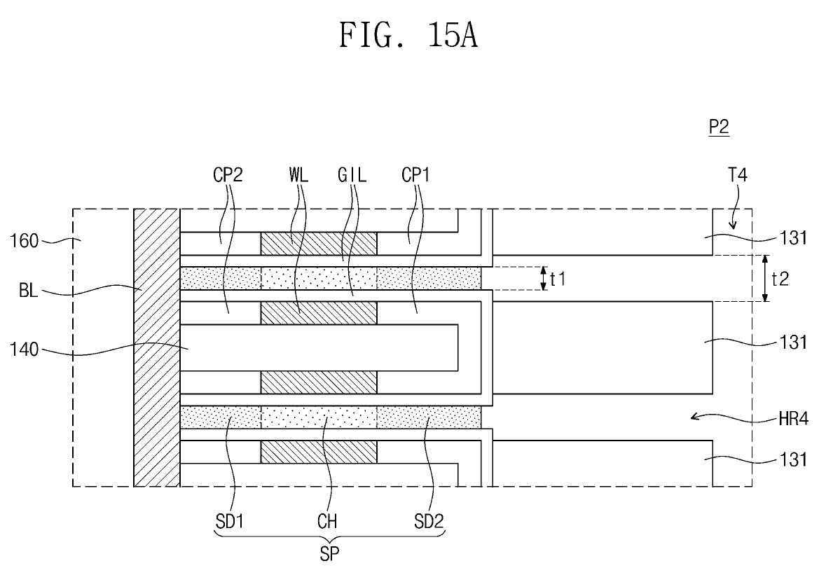

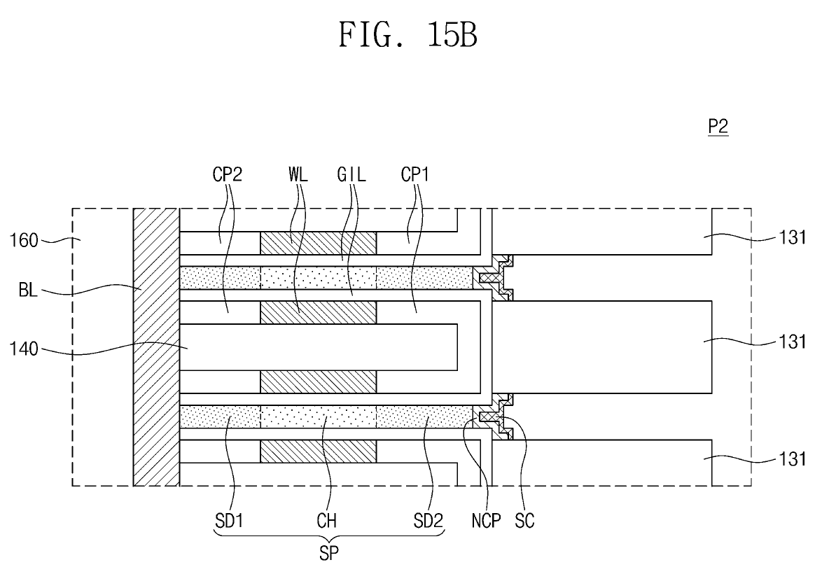

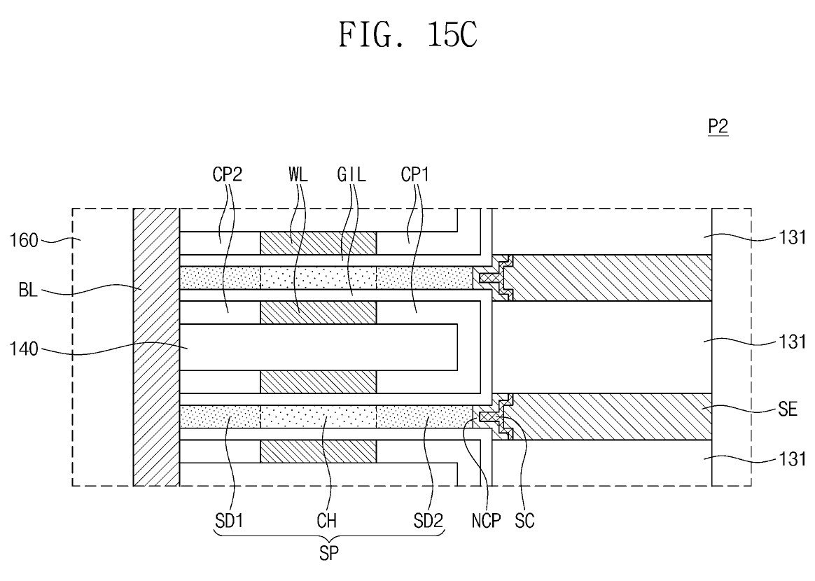

A method of forming the contact patterns NCP and the storage node electrodes SE will be described in more detail below with reference to FIGS. 14A to 14F and FIGS. 15A, 15B, 15C.

FIGS. 14A, 14B, 14C, 14D, and 14F, are enlarged views of a portion ‘P2’ of FIG. 13B to illustrate a method for manufacturing a semiconductor memory device according to embodiments of the disclosure.

Referring to FIG. 14A subsequent to FIG. 12B, after isotropically etching the portions of the semiconductor patterns SP to form the fourth horizontal regions HR4, second sidewalls of the semiconductor patterns SP may be laterally recessed than a sidewall of the gate insulating layer GIL between the third residual filling patterns 131 and the first capping pattern CP1. In other words, the fourth horizontal regions HR4 may expose a portion of the gate insulating layer GIL.

Then, dopants (e.g., phosphorus or boron) of the first conductivity type may be doped in portions of the semiconductor patterns SP exposed in the fourth horizontal regions HR4. Accordingly, the second dopant regions SD2 may be formed in the semiconductor patterns SP.

As a doping process for forming the second dopant regions SD2, a gas phase doping (GPD) process, a beam line ion implantation process, or a plasma assisted doping (PLAD) process may be performed. After performing the doping process, a heat treatment process may be performed. In other embodiment, the first and second dopant regions SD1, SD2 may be formed in the semiconductor layers 20 through the first trenches T1 during the process described in FIGS. 6A and 6B.

Referring to FIG. 14B, a contact layer 170 may be formed to conformally cover the inner surfaces of the fourth horizontal regions HR4 and contacts the second sidewalls of the semiconductor patterns SP. The contact layer 170 may be a doped polysilicon layer.

The contact layer 170 may be deposited to a substantially uniform thickness in the fourth horizontal regions HR4 by performing an atomic layer deposition (ALD) process or a chemical vapor deposition (CVD) process. The contact layer 170 may be deposited to have a second thickness smaller than one half of the first thickness of each semiconductor patterns SP in the third direction D3. For example, the contact layer 170 may be deposited to have a thickness of about 10 nm to 60 nm.

A dopant of the first conductivity type (e.g., phosphorus or boron) may be in-situ doped during deposition of the contact layer 170. The dopant concentration of the contact layer 170 may be greater than that of the second dopant regions SD2.

Referring to FIG. 14B, gap-fill patterns 171 may be formed to fill the fourth horizontal regions HR4 in which the contact layer 170 is formed. The gap-fill patterns 171 may include an insulating material having an etching selectivity with respect to the contact layer 170. For example, the gap-fill patterns 171 may include silicon nitride.

The forming the gap-fill patterns 171 may include depositing an insulating layer to fill the fourth horizontal regions HR4 in which the contact layer 170 is formed, and then etching portions of the insulating layer to expose a portion of the contact layer 170 on the sidewalls of the third residual filling patterns 131 so that portions of the insulating layer remain in the fourth horizontal regions HR4.

Referring to FIG. 14C, after the gap-fill patterns 171 are formed, a portion of the contact layer 170 may be laterally recessed to form contact patterns NCP separated from each other in the third direction D3. Forming the contact patterns NCP may include isotropically etching the contact layer 170 by using an etching recipe having an etching selectivity for the gap-fill patterns 171 and the third residual filling patterns 131.

After forming the contact patterns NCP, gap regions may be formed between the gap-fill patterns 171 and the third remaining filling patterns 131. Each of the contact patterns NCP may include a contact portion contacting the second sidewalls of the semiconductor patterns SP and a horizontal portion horizontally extending from the contact portion and disposed between the gap-fill patterns 171 and the third residual filling patterns 131. After forming the contact patterns NCP, the gap-fill patterns 171 may be removed.

Referring to FIG. 14D, after removing the gap-fill patterns 171, silicide patterns SC may be formed on the contact patterns NCP, respectively. The silicide patterns SC may include metal silicides (e.g., silicides of Ti, Mo, W, Cu, Al, Ta, Ru, Ir, Co, etc.).

In some embodiments, forming the silicide pattern SC may include providing a metal material into the fourth horizontal regions HR4 in which the contact patterns NCP are formed and then performing an annealing process. The metal material provided into the fourth horizontal regions HR4 may react with the semiconductor patterns SP to form silicide patterns SC. The silicide patterns SC may be conformally formed on the surfaces of the contact patterns NCP. For example, the silicide patterns SC may have a side surface in a wedge shape or a concavo-convex shape.

Referring to FIG. 14E, after forming the silicide patterns SC, storage node electrodes SE may be formed to fill the fourth horizontal regions HR4.

Forming the storage node electrodes SE may include depositing a conductive layer conformally covering the inner surfaces of the second trenches T2 and the fourth horizontal regions HR4 in which the contact patterns NCP and the silicide patterns SC are formed, and removing portions of the conductive layer deposited on the inner surfaces of the second trenches T2 so that the conductive patterns remain locally in the fourth horizontal regions HR4.

The storage node electrodes SE may be spaced apart from each other in the first direction D1, the second direction D2, and the third direction D3. The storage node electrodes SE may contact the silicide patterns SC exposed in the fourth horizontal regions HR4. Each of the storage node electrodes SE may have a pillar shape having a long axis in the second direction D2. The storage node electrode SE may include at least one of a metal material, a metal nitride layer, or a metal silicide.

Referring to FIG. 14F, portions of the gate insulating layer GIL and upper and lower surfaces of the storage node electrodes SE may be exposed by removing the third residual filling patterns 131. In some embodiments, portions of the third residual filling patterns 131 may remain, after laterally recessing the third residual filling pattern 131.

Further, when the third residual filling patterns 131 are removed, horizontal portions of the contact patterns NCP may be exposed. Thereafter, a capacitor dielectric layer conformally covering the storage node electrodes SE and a plate electrode may be sequentially formed.

FIGS. 15A, 15B, and 15C, enlarged views of a portion ‘P2’ of FIG. 13B. to illustrate a method for manufacturing a semiconductor memory device according to embodiments of the disclosure.

Referring to FIG. 15A subsequent to FIG. 12B, after forming the fourth trench T4, the vertical thickness t2 of each of the fourth horizontal regions HR4 may be greater than the first thickness t1 of each of the semiconductor patterns SP by a process of recessing portions of the semiconductor patterns SP exposed by the fourth trench T4. Accordingly, a part of a sidewall of the gate insulating layer GIL and the second sidewalls of the semiconductor patterns SP may be exposed in the fourth horizontal regions HR4.

Referring to FIG. 15B, contact patterns NCP may be formed in each of the fourth horizontal regions HR4 as described above with reference to FIGS. 14B and 14C.

Due to the difference between the thickness of the semiconductor patterns SP and the thickness of the fourth horizontal regions HR4, each of the contact patterns NCP may include first and second horizontal portions HP1, HP2, as described with reference to FIG. 3B.

Silicide patterns SC may then be formed on the contact patterns NCP, as described with reference to FIG. 14D. Here, each of the silicide patterns SC may have a region laterally recessed.

Referring to FIG. 15C, as described with reference to FIG. 14E, the storage node electrodes SE may be formed in the fourth horizontal regions HR4 in which the contact patterns NCP and the silicide patterns SC are formed. Thereafter, the third residual filling patterns 131 may be removed, and a capacitor dielectric layer conformally covering the storage node electrodes SE and a plate electrode may be sequentially formed.

According to some embodiments of the disclosure, a semiconductor memory device may include memory cells three-dimensionally stacked, a contact pattern having a concavity and convexity or a wedge may be disposed between the semiconductor patterns and the storage node electrode, thereby reducing contact resistance between the semiconductor patterns and the storage electrode. Accordingly, characteristics of a semiconductor memory device including memory cells three-dimensionally arranged can be improved.

According to some embodiments of the present disclosure, a method for manufacturing a semiconductor memory device may include forming semiconductor patterns on a substrate, the semiconductor patterns being spaced apart from each other in a first direction parallel to a top surface of the substrate and having a long axis in a second direction intersecting the first direction, forming a stacked structure including interlayer insulating layers and word lines alternately stacked in a third direction perpendicular to the top surface of the substrate. Each of the word lines surrounds the semiconductor patterns arranged along the first direction and extends along the first direction, forming sacrificial patterns having horizontal regions exposing end portions of the semiconductor patterns at one side of the stacked structure, forming a contact layer conformally covering inner walls of the horizontal regions and contacting the end portions of the semiconductor patterns, forming gap-fill patterns filling the horizontal regions in which the contact layer is formed, laterally recessing a portion of the contact layer to form contact patterns each contacting contact the end portions of the semiconductor patterns, and after removing the gap-fill patterns, forming storage node electrodes in the horizontal regions in which the contact patterns are formed.

In some embodiments, the contact layer may include depositing an in-situ doped polysilicon layer.

In some embodiments, the method may further include: doping a dopant of the first conductivity type to the end portions of the semiconductor patterns to form dopant regions, before forming the contact layer.

In some embodiments, a dopant concentration in the polysilicon layer may be greater than a dopant concentration of the dopant regions.

In some embodiments, each of the semiconductor patterns may have a first thickness in the third direction. The contact layer may be deposited with a second thickness that is less than one half of the first thickness.

In some embodiments, the method may further include: forming silicide patterns on surfaces of the contact patterns, after forming the contact patterns.

In some embodiments, each of the contact patterns may include a contact portion between the end portions of the semiconductor patterns and the gap-fill pattern and a horizontal portion between the sacrificial patterns and the gap-fill pattern.

In some embodiments, the method may further include forming silicide patterns on surfaces of the contact patterns, respectively, before forming the storage electrodes.

In some embodiments, each of the silicide patterns may have a side surface recessed toward the semiconductor patterns.

While embodiments are described above, a person skilled in the art may understand that many modifications and variations are made without departing from the spirit and scope of the disclosure defined in the following claims. Accordingly, the example embodiments of the disclosure should be considered in all respects as illustrative and not restrictive, with the spirit and scope of the disclosure being indicated by the appended claims.

What is claimed is:

1. A semiconductor memory device comprising:
a substrate;
a word line extending in a first direction parallel to a top surface of the substrate;
a semiconductor pattern penetrating the word line and comprising a long axis in a second direction intersecting the first direction;
a gate insulating layer between the word line and the semiconductor pattern;
a bit line extending in a third direction perpendicular to the top surface of the substrate and connected to a first end of the semiconductor pattern;
a storage node electrode connected to a second end opposite the first end of the semiconductor pattern; and
a contact pattern between the storage node electrode and the second end of the semiconductor pattern,
wherein the contact pattern comprises a contact portion contacting the semiconductor pattern and a horizontal portion extending from the contact portion in the second direction to define a recess region.

2. The semiconductor memory device of claim 1, wherein in the third direction, a thickness of the horizontal portion of the contact pattern is less than one half of a thickness of the semiconductor pattern.

3. The semiconductor memory device of claim 1, wherein, in the third direction, the semiconductor pattern comprises a first thickness, and the storage node electrode comprises a second thickness that is greater than the first thickness.

4. The semiconductor memory device of claim 1, wherein the contact portion of the contact pattern comprises a first length in the third direction, and
wherein, in the third direction, a distance between a top surface of the horizontal portion of the contact pattern and a bottom surface of the horizontal portion of the contact pattern is greater than the first length of the contact portion.

5. The semiconductor memory device of claim 1, wherein a portion of the storage node electrode is within the recess region.

6. The semiconductor memory device of claim 1, wherein a top surface of the storage node electrode is substantially coplanar with a top surface of the horizontal portion of the contact pattern, and
wherein a bottom surface of the storage node electrode is substantially coplanar with a bottom surface of the horizontal portion of the contact pattern.

7. The semiconductor memory device of claim 1, wherein the semiconductor pattern comprises a first dopant region and a second dopant region spaced apart in the second direction and a channel region between the first dopant region and the second dopant region,
wherein the first dopant region comprises a first dopant concentration,
wherein the second dopant region comprises a second dopant concentration,
wherein the contact pattern comprises polysilicon comprising a third dopant concentration, and
wherein the third dopant concentration is greater than the first dopant concentration and the second dopant concentration.

8. The semiconductor memory device of claim 7, further comprising:
a first capping pattern surrounding the first dopant region of the semiconductor pattern between the bit line and the word line; and
a second capping pattern surrounding the second dopant region of the semiconductor pattern between the word line and the storage node electrode,
wherein an interface between the semiconductor pattern and the contact pattern is misaligned with a first sidewall of the second capping pattern.

9. The semiconductor memory device of claim 1, further comprising a silicide pattern between the storage node electrode and the contact pattern,
wherein the silicide pattern comprises a second recess region, and
wherein a portion of the storage node electrode is within the second recess region.

10. A semiconductor memory device comprising:
a substrate;
a stacked structure comprising word lines and interlayer insulating patterns alternately stacked on the substrate, the word lines extending in a first direction parallel to a top surface of the substrate;
semiconductor patterns intersecting the word lines and having a long axis in a second direction parallel to the top surface of the substrate, the semiconductor patterns spaced apart on the substrate in the first direction and in a third direction perpendicular to the top surface of the substrate;
bit lines disposed at one side of the stacked structure and spaced apart in the first direction, each of the bit lines respectively connected to first ends of the semiconductor patterns spaced apart in the third direction;
storage node electrodes respectively connected to second ends of the semiconductor patterns opposite the first ends;
contact patterns between the storage node electrodes and the second ends of the semiconductor patterns, respectively;
a capacitor dielectric layer on the storage node electrodes; and
a plate electrode on the capacitor dielectric layer,
wherein each of the contact patterns comprises a contact portion contacting the semiconductor patterns, respectively, and a horizontal portion extending from the contact portion in the second direction to define a recess region, and
wherein, in the third direction, each of the semiconductor patterns comprises a first thickness, and each of the storage node electrodes comprises a second thickness that is greater than the first thickness.

11. The semiconductor memory device of claim 10, wherein the contact patterns comprise polysilicon doped with dopants.

12. The semiconductor memory device of claim 10, further comprising silicide patterns between the contact patterns and the storage node electrodes, respectively.

13. The semiconductor memory device of claim 10, wherein the contact portion of each of the contact patterns comprises, in the third direction, a first width substantially equal to the first thickness of each of the semiconductor patterns, and
wherein the horizontal portion of each of the contact patterns comprises a second width equal to the second thickness of each of the storage node electrodes, in the third direction.

14. The semiconductor memory device of claim 10, wherein each of the semiconductor patterns comprises a first dopant region adjacent a respective one of the bit lines, a second dopant region adjacent a respective one of the storage node electrodes, and a channel region overlapping the word lines between the first dopant region and the second dopant region,
wherein each first dopant region comprises a first dopant concentration, each second dopant region comprises a second dopant concentration, and each contact pattern comprises a third dopant concentration, and
wherein the third dopant concentration is greater than the first dopant concentration and the second dopant concentration.

15. The semiconductor memory device of claim 14, further comprising:
first capping patterns surrounding, respectively, each first dopant region between the bit lines and the word lines, respectively; and
second capping patterns surrounding, respectively, each second dopant region between the storage node electrodes and the word lines, respectively.

16. The semiconductor memory device of claim 15, wherein interfaces respectively between the contact patterns and the semiconductor patterns are respectively misaligned with first sidewalls of the second capping patterns.

17. The semiconductor memory device of claim 10, wherein each of the word lines surrounds, respectively, portions of the semiconductor patterns at a same level and extends in the first direction.

18. A semiconductor memory device comprising:
a substrate;
a stacked structure comprising word lines and interlayer insulating patterns alternately stacked on the substrate, the word lines extending in a first direction parallel to a top surface of the substrate;
semiconductor patterns traversing the word lines and having a long axis in a second direction parallel to the top surface of the substrate, the semiconductor patterns being spaced apart in the first direction and in a third direction perpendicular to the top surface the substrate;
bit lines extending in the third direction and spaced apart in the first direction, each of the bit lines respectively connected to first ends of the semiconductor patterns spaced apart in the third direction;
storage node electrodes respectively connected to second ends of the semiconductor patterns opposite the first ends;
contact patterns respectively between the storage node electrodes and the second ends of the semiconductor patterns;
silicide patterns respectively between the storage node electrodes and the contact patterns;
a capacitor dielectric layer on the storage node electrodes; and
a plate electrode on the capacitor dielectric layer,
wherein each of the contact patterns comprises a contact portion contacting the semiconductor patterns, respectively, and a horizontal portion extending from the contact portion in the second direction,
wherein each of the silicide patterns comprises a recess region, and
wherein a portion of each of the storage node electrodes is, respectively, within each recess region.

19. The semiconductor memory device of claim 18, wherein each of the semiconductor patterns comprises a first dopant region and a second dopant region spaced apart in the second direction and a channel region therebetween,
wherein each first dopant region comprises a first dopant concentration,
wherein each second dopant region comprises a second dopant concentration,
wherein each of the contact patterns comprises polysilicon comprising a third dopant concentration, and
wherein the third dopant concentration is greater than the first dopant concentration and the second dopant concentration.

20. The semiconductor memory device of claim 18, wherein, in the third direction, a thickness of each horizontal portion is less than one half of a thickness of each of the semiconductor patterns.
